(19) United States
(12) Patent Application Publication
(10) Pub. No.: US 2007/0257277 A1
(43) Pub. Date: Nov. 8, 2007

(54) Semiconductor Device and Method for Manufacturing the Same

(75) Inventors: Koichi Takeda, Minato-ku (JP); Hitoshi Wakabayashi, Minato-ku (JP); Kiyoshi Takeuchi, Minato-ku (JP); Shigeharu Yamagami, Minato-ku (JP); Masahiro Nomura, Minato-ku (JP); Masayasu Tanaka, Minato-ku (JP); Koichi Terashima, Minato-ku (JP); Risho Koh, Minato-ku (JP); Katsuhiko Tanaka, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 11/570,025

(22) PCT Filed: May 7, 2005
(86) PCT No.: PCT/JP05/09796

§ 371 Date: Mar. 12, 2007

(30) Foreign Application Priority Data
Jun. 4, 2004 (JP) 2004-167262

(51) Int. Cl. H01L 21/8244; H01L 21/82

(52) U.S. Cl. 257/204; 438/129; 257/E21.661; 257/E21.602; 257/E27.07

(57) ABSTRACT

A semiconductor device having SRAM cell units each comprising a pair of driving transistors, a pair of load transistors and a pair of access transistors, in which each of the transistors has a semiconductor layer projecting upward from a substrate plane, a gate electrode extending on opposite sides of the semiconductor layer so as to stride over a top of the semiconductor layer, a gate insulting film interposed between the gate electrode and the semiconductor layer, and a pair of source/drain areas formed in the semiconductor layer; a longitudinal direction of each semiconductor layer extends along a first direction; and between the adjacent SRAM cell units in the first direction, the semiconductor layer in one of the corresponding transistors is located on a center line of the semiconductor layer in the other transistor which center line extends along the first direction.

### TECHNNICAL FIELD

The present invention relates to a semiconductor device and a method for manufacturing this semiconductor device, and in particular, to a semiconductor storage device comprising a SRAM (Static Random Access Memory) and a method for manufacturing this semiconductor device.

### BACKGROUND ART

SRAM memory cells that are semiconductor storage elements have a basic structure described below.

As shown in a circuit diagram in FIG. 1, the SRAM memory cell is composed of a flip flop circuit serving as an information storage section, and a pair of access transistors A₁ and A₂ which controls the conduction between and the flip flop circuit and data lines (bit lines BL₁ and BL₂) through which information is written or read. The flip flop circuit is composed of, for example, a pair of CMOS inverters each composed of one driving transistor D₁ (D₂) and one load transistor L₁ (L₂).

One of source and drain areas of the access transistor A₁ (A₂) is connected to a drain of the load transistor L₁ (L₂) and driving transistor D₁ (D₂).

The other is connected to the bit line BL₁ (BL₂). Further, gates of the pair of access transistors A₁ and A₂ each constitute a part of a word line WL and are connected together.

A gate of the driving transistor D₁ and load transistor L₁ constituting one of the CMOS inverters is connected to a drain (storage node N₂) of the driving transistor D₂ and load transistor L₂ constituting the other CMOS inverter. Further, a gate of the driving transistor D₂ and load transistor L₂ constituting the latter CMOS inverter is connected to a drain (storage node N₁) of the driving transistor D, and load transistor L₁ constituting the former CMOS inverter. Thus, between the pair of CMOS inverters, the I/O section of one of the CMOS inverters is cross coupled to the gate of the other CMOS inverter via a pair of wires I₁ and I₂ called local wires.

A reference voltage (Vss, for example, GND) is supplied to a source area of each of the driving transistors D₁ and D₂. A power supply voltage (VDD) is supplied to a source area of each of the load transistors L₁ and L₂.

The above SRAM cell offers excellent element characteristics such as its resistance to noise and low power consumption during standby. However, the SRAM cell disadvantageously requires a larger cell area because of the need for six transistors for one memory cell, the need for a large number of wires, and the need for the element isolation between a p-type MOS and an n-type MOS in the same cell.

As one type of MIS type field effect transistor (hereinafter referred to as “FET”), what is called an FIN type FET has been proposed. The FIN type FET has a rectangular parallelepiped semiconductor portion that projects perpendicularly to a substrate plane and a gate electrode that strides over a top surface of the rectangular parallelepiped semiconductor portion from one side to the other side. A gate insulating film is interposed between the rectangular parallelepiped semiconductor portion and the gate electrode. A channel is formed mainly along the opposite sides of the rectangular parallelepiped semiconductor portion. Such a FIN type FET is known to be advantageous for miniaturization because the channel width can be set perpendicularly to a substrate plane. The FIN type FET is also known to be advantageous for the improvement of various characteristics such as the improvement of a cutoff characteristic and carrier mobility and the reduction of a short channel effect and punch through.

As such a FIN type FET, Patent Document 1 (Japanese Patent Laid-Open No. 64-8670) discloses a MOS field effect transistor characterized in that a semiconductor portion having a source area, a drain area, and a channel area is shaped like a rectangular parallelepiped having sides almost perpendicular to the plane of a wafer substrate, in that the height of the rectangular parallelepiped semiconductor portion is larger than its width, and in that a gate electrode extends perpendicularly to the plane of the wafer substrate.

Patent Document 1 illustrates a form in which a part of the rectangular parallelepiped semiconductor portion is a part of the silicon wafer substrate and a form in which a part of the rectangular parallelepiped semiconductor portion is a part of a single crystal silicon layer in an SOI (Silicon On Insulator) substrate. The former is shown in FIG. 2(a) and the latter is shown in FIG. 2(b).

In the form shown in FIG. 2(a), a part of a silicon wafer substrate 101 is a rectangular parallelepiped portion 103. A gate electrode 105 extends along the opposite sides of the rectangular parallelepiped portion 103 over its top. The rectangular parallelepiped portion 103 has a source area and a drain area formed opposite the respective sides of the gate electrode. A channel is formed under an insulating film 104 under the gate electrode. The channel width is equal to double the height h of the rectangular parallelepiped portion 103. The gate length corresponds to the width L of the gate electrode 105. The rectangular parallelepiped portion 103 is composed of an inner unetched part of a trench formed by anisotropically etching the silicon wafer substrate 101. The gate electrode 105 is provided on an insulating film 102 formed in the trench so as to stride over the rectangular parallelepiped portion 103.

In the form shown in FIG. 2(b), an SOI substrate is provided which comprises a silicon wafer substrate 111, an insulating layer 112, and a silicon single crystal layer. The silicon single crystal layer is patterned to form a rectangular parallelepiped portion 113. A gate electrode 115 is provided on the exposed insulating layer 112 so as to stride over the rectangular parallelepiped portion 113. The rectangular parallelepiped portion 113 has a source area and a drain area formed opposite the respective sides of a gate electrode. A channel is formed under an insulating film 114 under the gate electrode. The channel width is equal to the sum of double the height a of the rectangular parallelepiped portion 113 and the width b of the rectangular parallelepiped portion 113. The gate length corresponds to the width L of the gate electrode 115.

On the other hand, Patent Document 2 (Japanese Patent Laid-Open No. 2002-118255) discloses a FIN type FET having a plurality of rectangular parallelepiped semiconductor portions (projecting semiconductor layers 213), for example, as shown in FIGS. 3(a) to 3(c). FIG. 3(b) is a sectional view taken along line B-B in FIG. 3(a). FIG. 2(c) is a sectional view taken along line C-C in FIG. 3(a). This FIN type FET has the plurality of projecting semiconductor layers 213 composed of a part of a well layer 211 in a silicon substrate 210 and arranged parallel to one another. A gate electrode 216 is provided so as to stride over the central part of these projecting semiconductor layers. The gate electrode 216 is formed so as to extend from a top surface of an insulating film 214 along the sides of the projecting semiconductor layers 213. An insulating film 218 is interposed between the projecting semiconductor layers and the gate electrode. A channel 215 is formed in the projecting semiconductor layer under the gate electrode. Further, a source/drain area 217 is formed in each projecting semiconductor layer. A high concentration impurity layer (punch through stopper layer) is provided in an area 212 under the source/drain area 217. Upper layer wires 229 and 230 are provided via an interlayer insulating film 226 and are connected to the source/drain area 207 and the gate electrode 216, respectively, via contact plugs 228. Patent Document 2 states that this structure enables the sides of the projecting semiconductor layer to be used as the channel width, allowing the planar area to be reduced compared to conventional planar FETs.

In recent years, attempts have been made to apply these FIN type FETs to SRAMs. For example, Patent Document 3 (Japanese Patent Laid-Open No. 2-263473) describes an example in which FIN type FETs are applied to some of the transistors (having gates composed of word lines) constituting memory cells in a SRAM. Non-Patent Document 1 (Fu-Liang Yang et al, IEDM (International Electron Devices Meeting), 2003, p. 627 to 630) shows the possibility of applying FIN type FETs to a SRAM. Non-Patent Document 2 (T. Part et al, IEDM, 2003, p. 27 to 30) and Non-Patent Document 3 (Jeong-Hwan Yang et al, IEDM, 2003, p. 23 to 26) describe examples in which FIN type FETs are applied to a SRAM.

### DISCLOSURE OF THE INVENTION

An object of the present invention is to provide a semiconductor device comprising a SRAM that uses FIN type FETs and having a dense structure that is easy to manufacture.

The present invention includes aspects described in the following items (1) to (22) below.

(1) A semiconductor device having SRAM cell units each comprising a pair of a first driving transistor and a second driving transistor, a pair of a first load transistor and a second load transistor, and a pair of a first access transistor and a second access transistor, wherein:

each of the transistors comprises a semiconductor layer projecting upward from a substrate plane, a gate electrode extending on opposite sides of the semiconductor layer so as to stride over a top of the semiconductor layer, a gate insulting film interposed between the gate electrode and the semiconductor layer, and a pair of source/drain areas formed in the semiconductor layer;

a longitudinal direction of each semiconductor layer extends along a first direction; and

between the adjacent SRAM cell units in the first direction, the semiconductor layer in one of the corresponding transistors is located on a center line of the semiconductor layer in the other transistor which center line extends along the first direction.

(2) A semiconductor device having SRAM cell units each comprising a pair of a first driving transistor and a second driving transistor, a pair of a first load transistor and a second load transistor, and a pair of a first access transistor and a second access transistor, wherein:

each of the transistors comprises a semiconductor layer projecting upward from a substrate plane, a gate electrode extending on opposite sides of the semiconductor layer so as to stride over a top of the semiconductor layer, a gate insulting film interposed between the gate electrode and the semiconductor layer, and a pair of source/drain areas formed in the semiconductor layer;

the semiconductor layers are arranged so that a longitudinal direction of each semiconductor layer extends along a first direction and so that intervals between center lines of the semiconductor layers which center lines extend along the first direction are each an integral multiple of the minimum one of the intervals;

the semiconductor layers have an equal width in a second direction which is parallel to the substrate plane and perpendicular to the first direction; and

between the adjacent SRAM cell units in the first direction, the semiconductor layer in one of the corresponding transistors is located on a center line of the semiconductor layer in the other transistor which center line extends along the first direction.

(3) The semiconductor device according to item (2), wherein in the SRAM cell unit,

the first driving transistor comprises a semiconductor layer placed on a center line of the semiconductor layer of the first access transistor which center line extends along the first direction, and the second driving transistor has a semiconductor layer placed on a center line of the semiconductor layer of the second access transistor which center line extends along the first direction;

the first load transistor comprises a semiconductor layer adjacent to the semiconductor layer of the first driving transistor, and the second load transistor has a semiconductor layer adjacent to the semiconductor layer of the second driving transistor; and

the first load transistor and the second load transistor are arranged so that the interval between the center line of the semiconductor layer of the first load transistor and the center line of the semiconductor layer of the second load transistor is equal to the minimum interval.

(4) The semiconductor device according to item (2), wherein in the SRAM cell unit,

the first load transistor comprises a semiconductor layer placed on a center line of the semiconductor layer of the first access transistor which center line extends along the first direction, and the second load transistor has a semiconductor layer placed on a center line of the semiconductor layer of the second access transistor which center line extends along the first direction;

the first driving transistor comprises a semiconductor layer adjacent to the semiconductor layer of the first load transistor, and the second driving transistor has a semiconductor layer adjacent to the semiconductor layer of the second load transistor; and

the first driving transistor and the second driving transistor are arranged so that the interval between the center line of the semiconductor layer of the first driving transistor and the center line of the semiconductor layer of the second driving transistor is equal to the minimum interval.

(5) The semiconductor device according to item (2), (3), or (4), wherein the interval between the center lines extending along the first direction of the semiconductor layers of the first driving transistor and the first load transistor which are adjacent to each other is at least double the minimum interval; and

the interval between the center lines extending along the first direction of the semiconductor layers of the second driving transistor and the second load transistor which are adjacent to each other is at least double the minimum interval.

(6) The semiconductor device according to any one of items (2) to (5), wherein between the adjacent SRAM cell units in the second direction, the access transistors of one and the other of the SRAM cell units are arranged adjacent to each other, and the interval between the center lines extending along the first direction of the semiconductor layers of one and the other of the access transistors is at least double the minimum interval.

(7) The semiconductor device according to any one of item (2) to (6), wherein each of the semiconductor layers constituting the transistors in the SRAM cell unit is made of a semiconductor layer provided on an insulating layer.

(8) The semiconductor device according to item (7), wherein in the SRAM cell unit, the first driving transistor has a semiconductor layer integrated with the semiconductor layer of the first access transistor and the semiconductor layer of the first load transistor, and the second driving transistor has a semiconductor layer integrated with the semiconductor layer of the second access transistor and the semiconductor layer of the second load transistor.

(9) The semiconductor device according to item (7), wherein the SRAM cell unit has, on the insulating layer, a first semiconductor layer area integrated with the semiconductor layer of the first driving transistor, the semiconductor layer of the first load transistor and the semiconductor layer of the first access transistor and having a junction between an area of a first conductivity type and an area of a second conductivity type together, and a second semiconductor layer area integrated with the semiconductor layer of the second driving transistor, the semiconductor layer of the second load transistor and the semiconductor layer of the second access transistor and having a junction between an area of the first conductivity type and an area of the second conductivity type together; and

a first node contact connected to a drain area of the first driving transistor and to a drain area of the first load transistor is connected to the first semiconductor layer area, and a second node contact connected to a drain area of the second driving transistor and to a drain area of the second load transistor is connected to the second semiconductor layer area.

(10) The semiconductor device according to item (1), wherein in the SRAM cell unit,

each of the semiconductor layers constituting the transistors is made of a semiconductor layer provided on an insulating layer; and

the first driving transistor has a semiconductor layer integrated with the semiconductor layer of the first access transistor and the semiconductor layer of the first load transistor, and the second driving transistor has a semiconductor layer integrated with the semiconductor layer of the second access transistor and the semiconductor layer of the second load transistor.

(11) The semiconductor device according to item (1), wherein in the SRAM cell unit,

each of the semiconductor layers constituting the transistors is made of a semiconductor layer provided on an insulating layer;

the SRAM cell unit has, on the insulating layer, a first semiconductor layer area integrated with the semiconductor layer of the first driving transistor, the semiconductor layer of the first load transistor and the semiconductor layer of the first access transistor and having a junction between an area of the first conductivity type and an area of the second conductivity type together, and a second semiconductor layer area integrated with the semiconductor layer of the second driving transistor, the semiconductor layer of the second load transistor and the semiconductor layer of the second access transistor and having a junction between an area of the first conductivity type and an area of the second conductivity type together; and

the first node contact connected to a drain area of the first driving transistor and to a drain area of the first load transistor is connected to the first semiconductor layer area, and the second node contact connected to a drain area of the second driving transistor and to a drain area of the second load transistor is connected to the second semiconductor layer area.

(12) The semiconductor device according to any one of items (1) to (6), wherein each of the semiconductor layers constituting the transistors in the SRAM cell unit is formed of a part of a semiconductor substrate and projects from a top surface of an isolating insulating film on the semiconductor substrate.

(13) The semiconductor device according to any one of items (1) to (12), wherein in the SRAM cell unit,

the gate electrode of the first driving transistor and the gate electrode of the first load transistor are formed of a first wire extending along the second direction perpendicular to the first direction, and the gate electrode of the second driving transistor and the gate electrode of the second load transistor are formed of a second wire extending along the second direction; and

the gate electrode of the first access transistor is formed of a third wire placed on a center line of the second wire extending along the second direction and the gate electrode of the second access transistor is formed of a fourth wire placed on a center line of the first wire extending along the second direction.

(14) The semiconductor device according to any one of items (1) to (13), wherein a ground line contact connected to the source area of the first driving transistor, a power source line contact connected to the source area of the first load transistor, and a bit line contact connected to the source/drain area of the second access transistor are arranged on one line at one of cell unit boundaries extending along the second direction; and

a ground line contact connected to the source area of the second driving transistor, a power source line contact connected to the source area of the second load transistor, and a bit line contact connected to the source/drain area of the first access transistor are arranged on one line at the other cell unit boundary extending along the second direction.

(15) The semiconductor device according to any one of items (1) to (14), wherein each of the ground line contacts, the power source line contacts, and the bit line contacts has a width in the second direction which is larger than the width in the second direction of the semiconductor layer under the gate electrode, and is connected to a pad semiconductor layer integrated with the semiconductor layer.

(16) The semiconductor device according to any one of items (1) to (15), wherein the adjacent SRAM cell units are in a mirror image relationship with respect to the cell unit boundary, which serves as a symmetry axis.

(17) A method for manufacturing a semiconductor device having SRAM cell units each comprising a pair of a first driving transistor and a second driving transistor, a pair of a first load transistor and a second load transistor, and a pair of a first access transistor and a second access transistor, each of the transistors having a semiconductor layer projecting upward from a substrate plane, a gate electrode extending on opposite sides of the semiconductor layer so as to stride over a top of the semiconductor layer, a gate insulting film interposed between the gate electrode and the semiconductor layer, and a pair of source/drain areas formed in the semiconductor layer, the method comprising the steps of:

pattering a semiconductor layer to form a semiconductor pattern having a striped pattern in which elongate semiconductor layers extending in a first direction and having an equal width in a second direction perpendicular to the first direction are arranged at equal intervals;

removing a part of the striped pattern;

forming a gate insulating film on sides of the remaining elongate semiconductor layers;

depositing a gate electrode material and pattering the gate electrode material deposited film to form gate electrodes each extending on opposite surfaces of the elongate semiconductor layer along the second direction so as to stride over a top of the elongate semiconductor layer; and

doping impurities into each elongate semiconductor layer to form source/drain areas.

(18) The method for manufacturing a semiconductor device according to item (17), wherein the semiconductor layer patterns are line symmetric with respect to each of four sides of a rectangular unit boundary corresponding to a SRAM cell unit boundary, which serves as a symmetry axis.

(19) The method for manufacturing a semiconductor device according to item (17) or (18), wherein

in the step of forming the semiconductor layer pattern, a band-like pattern is formed which crosses the elongate semiconductor layer and which has a width in the first direction which is larger than the width in the second direction of the elongate semiconductor layer; and

in the step of removing a part of the striped pattern, a part of the band-like pattern is also removed to form a pad semiconductor layer having a width in the second direction which is larger than the width in the second direction of the elongate semiconductor layer, and a contact connected with upper layer wiring is connected to the pad semiconductor layer.

(20) The method for manufacturing a semiconductor device according to item (17), (18), or (19), further comprising a step of forming a cap insulating layer on the semiconductor layer, wherein the semiconductor layer and the cap insulating layer are patterned to form the semiconductor layer pattern on which the cap insulating layer is provided.

(21) The method for manufacturing a semiconductor device according to any one of items (17) to (20), wherein the semiconductor layer provided on an under insulating layer is patterned to form the semiconductor layer pattern provided on the under insulating layer.

(22) The method for manufacturing a semiconductor device according to any one of items (17) to (20), further comprising a step of patterning a semiconductor substrate to form the semiconductor layer pattern constituting the semiconductor layer and then providing an isolating insulation layer on the semiconductor substrate, and a step of removing a top surface part of the isolating insulation layer to expose the semiconductor layer pattern so that the semiconductor layer pattern projects upward from the top surface of the remaining isolating insulation film.

The present invention can provide a semiconductor device having a dense SRAM structure which is easy to manufacture and to which FIN type FETs are applied.

### BRIEF DESCRIPTION OF THE DRAWINGS

FIG. 1 is a circuit diagram of a SRAM;

FIG. 2 is a diagram illustrating an element structure of a conventional FIN type FET;

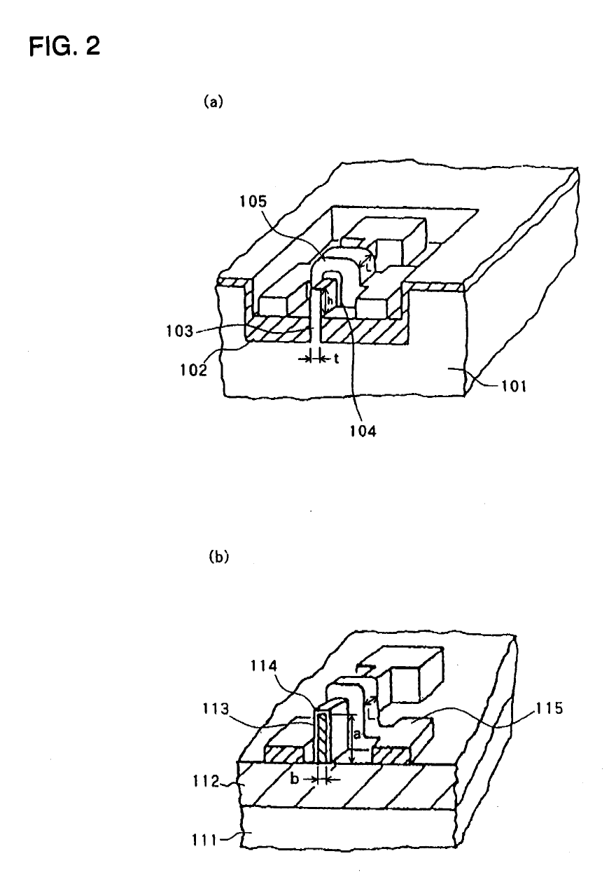

FIG. 3 is a diagram illustrating an element structure of a conventional FIN type FET;

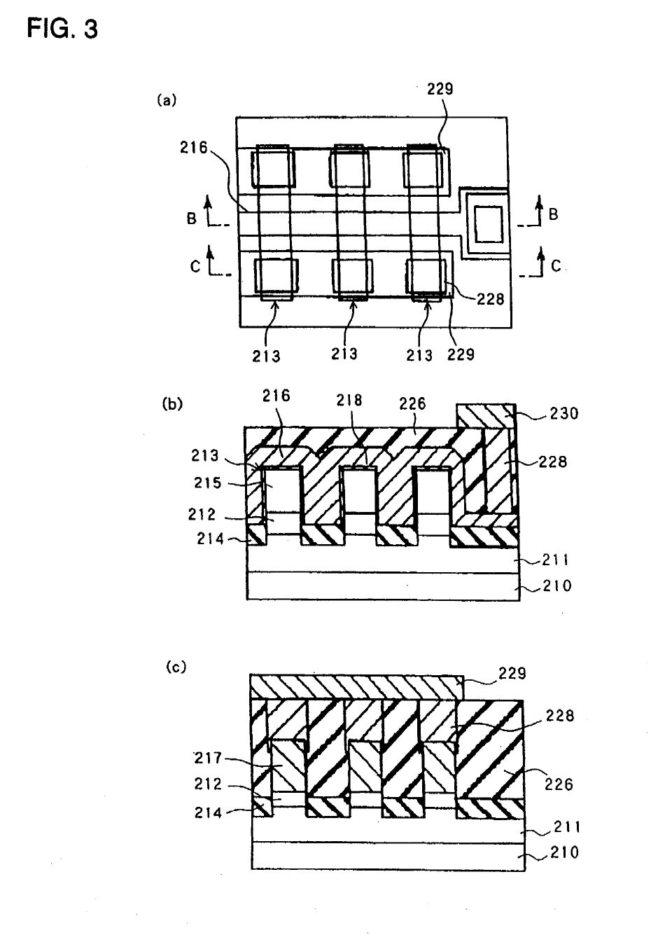

FIG. 4 is a diagram illustrating an element structure of an FIN type FET that is applied to the present invention;

FIG. 5 is a diagram illustrating an element structure of a SRAM cell unit according to the present invention (plan view);

FIG. 6 is a diagram illustrating the element structure of the SRAM cell unit according to the present invention (sectional view);

FIG. 7 is a diagram illustrating the element structure of the SRAM cell unit according to the present invention (sectional view);

FIG. 8 is a diagram illustrating a method for manufacturing a SRAM structure according to the present invention;

FIG. 9 is a diagram illustrating the method for manufacturing a SRAM structure according to the present invention;

FIG. 10 is a diagram illustrating the method for manufacturing a SRAM structure according to the present invention;

FIG. 11 is a diagram illustrating the method for manufacturing a SRAM structure according to the present invention;

FIG. 12 is a diagram illustrating another element structure of a SRAM cell unit according to the present invention;

FIG. 13 is a diagram illustrating another element structure of a SRAM cell unit according to the present invention;

FIG. 14 is a diagram illustrating another element structure of a SRAM cell unit according to the present invention;

FIG. 15 is a diagram illustrating another element structure of a SRAM cell unit according to the present invention;

FIG. 16 is a diagram illustrating another method for manufacturing a SRAM structure according to the present invention;

FIG. 17 is a diagram illustrating another element structure of a SRAM cell unit according to the present invention;

FIG. 18 is a diagram illustrating another element structure of a SRAM cell unit according to the present invention; and

FIG. 19 is a diagram illustrating another element structure of a SRAM cell unit according to the present invention (Sectional view).

### BEST MODE FOR CARRYING OUT THE INVENTION

[Configuration of a FIN Type FET]

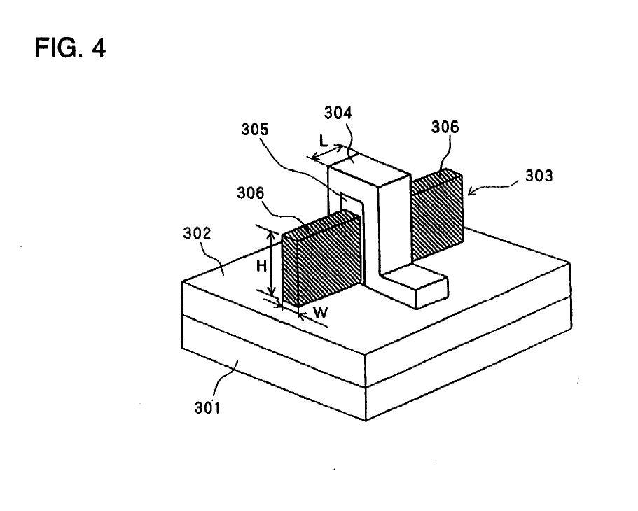

A FIN type FET that is applied to a SRAM structure according to the present invention may be a field effect transistor having a semiconductor layer 303 that projects upward perpendicularly to a substrate plane, a gate electrode 304 that extends on the opposite sides of the semiconductor layer so as to stride over its top, a gate insulating film 305 interposed between the gate electrode 304 and the semiconductor layer 303, and a source/drain area 306 formed in the semiconductor layer 303, for example, as shown in FIG. 4.

The semiconductor layer (hereinafter referred to as a “projecting semiconductor layer”) projecting upward perpendicularly to the substrate plane, constituting the FIN type FET, may be provided on a base insulating film 302 on a semiconductor substrate 301, for example, as shown in FIG. 4. In the present invention, the substrate plane is an arbitrary surface parallel to the substrate, in this case, the surface of the base insulating film. The base insulating film itself may be a substrate. Further, as described later, the semiconductor substrate may be patterned to form a semiconductor pattern so that the semiconductor layer portion projecting upward from the surface of the isolating insulation layer provided in the semiconductor pattern can be used as the projecting semiconductor layer of the FIN type FET. The latter configuration is advantageous in heat radiation and suppression of a substrate floating effect because the element can be driven to release heat or charges generated from the semiconductor layer to the semiconductor substrate. The projecting semiconductor layer of the FIN type FET may be shaped like a rectangular parallelepiped in accordance with machining accuracy. However, a shape different from the rectangular parallelepiped may be used provided that desired element characteristics are obtained.

In the FIN type FET according to the present invention, the gate electrode extends on the opposite sides of the projecting semiconductor layer so as to stride over its top. The gate insulating film is interposed between the gate electrode and the projecting semiconductor layer. Impurities are doped into a part under the gate electrode of the projecting semiconductor layer at a relatively low concentration depending on a predetermined threshold voltage. A voltage is applied to the gate electrode to form a channel. The insulating film interposed between each side (surface perpendicular to the substrate plane) of the projecting semiconductor layer and the gate electrode is allowed to function as a gate insulating film to enable a channel to be formed on the opposite sides of the projecting semiconductor layer. A thick cap insulating film can be provided between the top surface of the projecting semiconductor layer and the gate electrode to avoid forming a channel on the top surface of the projecting semiconductor layer. On the other hand, an insulating film that is as thin as the gate insulating film provided on the sides can be provided between the top surface of the projecting semiconductor layer and the gate electrode to allow a channel to be also formed on the top surface of the projecting semiconductor layer.

Here, the channel length direction is the longitudinal direction of the projecting semiconductor layer 303, that is, a gate length L direction. The source/drain area 306 is normally constructed on the opposite sides of the gate electrode of the projecting semiconductor layer 303 using a diffusion layer into which impurities of a high concentration are doped. Alternatively, what is called a schottky source/drain transistor may be provided by forming the source/drain area of metal.

The FIN type FET according to the present invention may have what is called a multi-structure in which a plurality of projecting semiconductor layers are arranged in one transistor in parallel and in which a conductor wire striding over the plurality of projecting semiconductor layers constitutes a gate electrode. An element structure relating to each projecting semiconductor layer may be similar to that described above. In connection with the uniformity of element characteristics and machining accuracy, the projecting semiconductor layers preferably have an equal width W (width parallel to the substrate plane and perpendicular to the channel length direction).

In the Fin type MISFET according to the present invention, a main channel is preferably formed on the opposite sides of the projecting semiconductor layer. Further, the width W of the projecting semiconductor layer under the gate electrode is preferably such that the semiconductor layer is completely depleted by a depletion layer formed from the opposite sides of the semiconductor layer during operation. This configuration is advantageous for the improvement of the cutoff characteristic and carrier mobility and the reduction of the substrate floating effect. An element structure providing this configuration is preferably such that the width W of the projecting semiconductor layer under the gate electrode is at most double the height H of the semiconductor layer or at most the gate length L. Specifically, in connection with machining accuracy, strength, and the like, the width W of the projecting semiconductor layer under the gate electrode is preferably set to at least 5 nm, more preferably at least 10 nm. On the other hand, a dominant channel is formed on the sides of the semiconductor layer, and is preferably set to at most 60 nm, more preferably at most 30 nm, in order to provide a completely depleted structure.

The specific dimensions and the like of the FIN type FET according to the present invention can be appropriately set, for example, as follows. The projecting semiconductor layer has a width W of 5 to 100 nm, a height of 20 to 200 nm, and a gate length of 10 to 100 nm. The gate insulating film has a thickness of 1 to 5 nm (in the case of SiO₂). The concentration of impurities in the channel formed area is 0 to 1×10¹⁹ cm⁻³. The concentration of impurities in the source/drain area is 1×10¹⁹ to 1×10²¹ cm⁻³. The height H of the projecting semiconductor layer means the length of a part of the semiconductor layer which projects upward from the surface of the base insulating film or isolating insulation film; the length is perpendicular to the substrate plane. Further, the channel formed area refers to a part of the projecting semiconductor layer which is located under the gate electrode.

In the above described element structure, a material for the base insulating film or isolating insulation film is not particularly limited provided that it has a desired insulating property. Examples of the material include metal oxide such as SiO₂, Si₃N₄, AlN, or alumina, and an organic insulating material.

The semiconductor forming the projecting semiconductor layer of the FIN type FET is preferably single crystal silicon.

The substrate under the base insulating film may be a silicon substrate. However, the present invention is not limited to the silicon substrate but can be established provided that an insulator is present under the projecting semiconductor layer. For example, a structure such as SOS (Silicon ON Sapphire, Silicon On Spinnel) may be used in which the insulator itself under the semiconductor layer constitutes a support substrate. The insulating support substrate may be, instead of the SOS, a quartz substrate or an AIN substrate. Manufacturing techniques (laminating process and thin film forming process) for SOI (Silicon On Insulator) enable the semiconductor layer to be provided on these support substrates.

A material for the gate electrode according to the present invention may be a conductor having a desired conductivity and a desired work function.

Examples of the material include, for example, impurities-doped semiconductor such as impurities-doped polycrystalline silicon, polycrystalline SiGe, polycrystalline Ge, or polycrystalline SiC, metal such as Mo, W, or Ta, metal nitride such as TiN or WN, and a silicide compound such as cobalt silicide, nickel silicide, platinum silicide, or erbium silicide. Further, the structure of the gate electrode may be, instead of a singe layer, a stack structure such as a stack film of a polycrystalline silicon film and a metal film, a stack film of metal films, or a stack film of a polycrystalline silicon film and a silicide film.

The gate insulating film according to the present invention may be an SiO₂ film or an SiON film, or what is called a high-dielectric-constant film (High-K film). Examples of the High-K film may include, for example, a metal oxide film such as a Ta₂O₅ film, an Al₂O₃ film, an La₂O₃ film, an HfO₂ film, or a ZrO₂ film, and composite metal oxide indicated by a composition formula such as HfSiO, ZrSiO, HfAlO, or ZrAlO. Further, the gate insulating film may have a stack structure, for example, a stack structure in which a silicon containing oxide film such as SiO₂ or HfSiO is formed on a semiconductor layer such as silicon, with a High-K film provided on the silicon containing oxide film.

[Circuit Configuration of the SRAM Cell Unit]

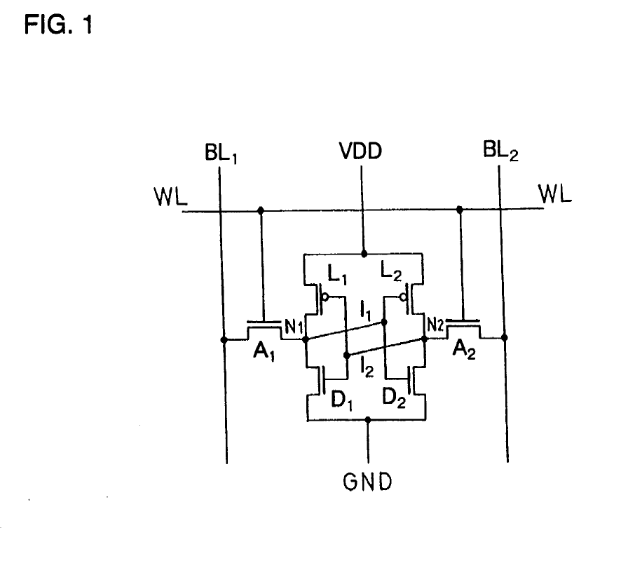

The SRAM memory cell unit preferable for the present invention has a circuit shown in the circuit diagram in FIG. 1. The SRAM memory cell unit has six transistors, a pair of driving transistors D₁ and D₂, a pair of load transistors L₁ and L₂, and a pair of access transistors A₁ and A₂. The paired driving transistors D₁ and D₂ and the paired access transistors A₁ and A₂ are field effect transistors of a first conductivity type (for example, an n channel type). The paired load transistors L₁ and L₂ are field effect transistors of a second conductivity type (for example, a p channel type).

The paired driving transistors D₁ and D₂ and the paired load transistors L₁ and L₂ constitute a flip flop circuit serving as an information storing section that stores 1-bit information. The flip flop circuit is composed of a pair of CMOS inverters each composed of one driving transistor D₁ (D₂) and one load transistor L₁ (L₂).

One of source and drain of the access transistor A₁ (A₂) is connected to drains of the load transistor L₁ (L₂) and driving transistor D₁ (D₂), with the other connected to a bit line BL₁ (BL₂). Gates of the paired access transistors A₁ and A₂ are connected to a word line WL.

A gate of the driving transistor D₁ and load transistor L₁ constituting one of the CMOS inverters is connected to a drain (storage node N₂) of the driving transistor D₂ and load transistor A₂ constituting the other CMOS inverter. Further, a gate of the driving transistor D₂ and load transistor L₂ constituting the latter CMOS inverter is connected to a drain (storage node N₁) of the driving transistor D₁ and load transistor L₁ constituting the former CMOS inverter. Thus, between the pair of CMOS inverters, the I/O section (storage node) of one of the CMOS inverters is cross coupled to the gate of the other CMOS inverter via a pair of wires I₁ and I₂ called local wires.

A reference voltage (for example, GND) is supplied to a source of the driving transistors D₁ and D₂. A power supply voltage (VDD) is supplied to a source of the load transistors L₁ and L₂.

[Element Structure of the SRAM]

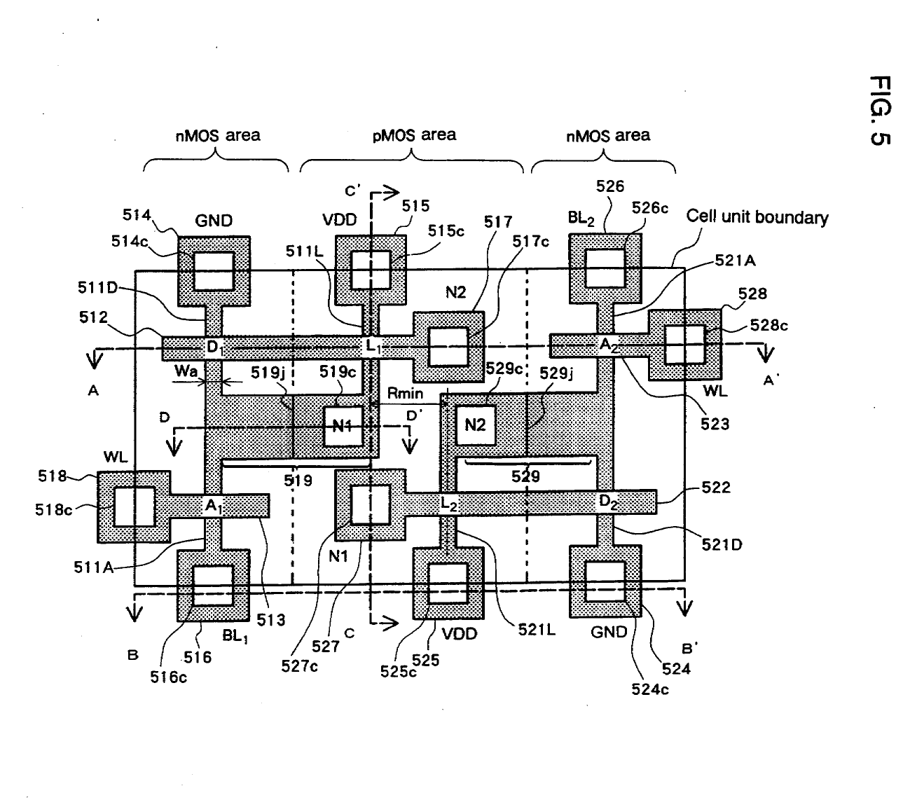

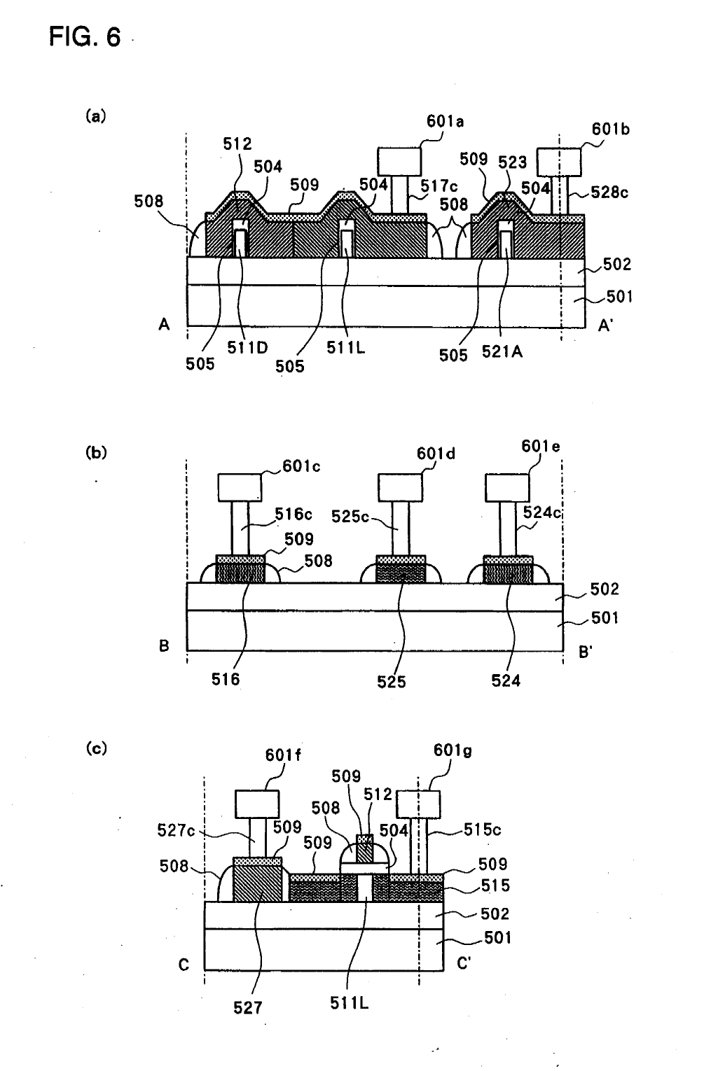

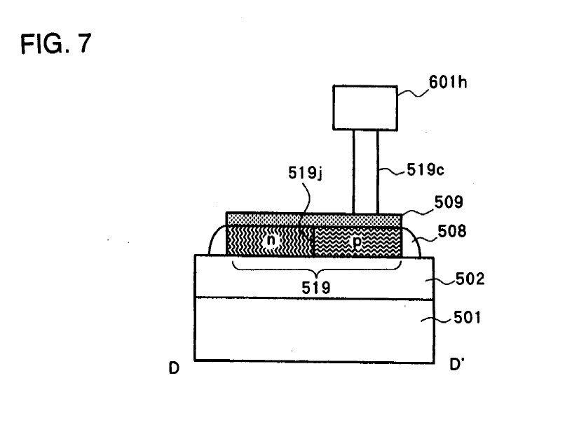

FIGS. 5 to 7 shows an example of an element structure of the SRAM cell unit. FIG. 5 is a plan view, FIG. 6(a) is a sectional view taken along line A-A′, and FIG. 6(b) is a sectional view taken along line B-B′. FIG. 6(c) is a sectional view taken along line C-C′, and FIG. 7 is a sectional view taken along line D-D′. In FIG. 5, side wall insulating films 508 are omitted. In FIGS. 6(a) to 6(c), vertical broken lines in the right and left of the figures indicate cell unit boundaries.

As shown in FIG. 5, inside the cell unit boundaries, the n-channel type driving transistors D₁ and D₂, the p-channel type load transistors L₁ and L₂, and the n-channel type access transistors A₁ and A₂ are arranged on an insulating layer 502 so as to constitute the circuit in FIG. 1; the insulating layer 502 is provided on a semiconductor substrate 501. The semiconductor layer portion in an nMOS area is an n-type area. The semiconductor layer portion in a pMOS area is a p-type area.

The driving transistor D₁ has a projecting semiconductor layer 511D, a gate electrode 512 extending on the opposite sides of the projecting semiconductor layer 511D so as to stride over its top, a gate insulating film 505 interposed between the gate electrode 512 and the projecting semiconductor layer 511D, and a source/drain area formed in the projecting semiconductor layer 511D on the opposite sides of the gate electrode (FIG. 6(a)). In this example, a cap insulating film 504 is provided between the top of the projecting semiconductor layer and the gate electrode. No channel is formed on the top surface of the projecting semiconductor layer. The other transistors also have cap insulating films. The other driving transistor D₂ has a projecting semiconductor layer 521D, a gate electrode 522 extending on the opposite sides of the projecting semiconductor layer 521D so as to stride over its top, the gate insulating film 505 interposed between the gate electrode 522 and the projecting semiconductor layer 521D, and a source/drain area formed in the projecting semiconductor layer 521D on the opposite sides of the gate electrode.

The load transistor L₁ has a projecting semiconductor layer 511L, the gate electrode 512 extending on the opposite sides of the projecting semiconductor layer 511L so as to stride over its top, the gate insulating film 505 interposed between the gate electrode 512 and the projecting semiconductor layer 511L, and a source/drain area formed in the projecting semiconductor layer 511L on the opposite sides of the gate electrode (FIGS. 6(a) and 6(c)). The other load transistor L₂ has a projecting semiconductor layer 521L, the gate electrode 522 extending on the opposite sides of the projecting semiconductor layer 521L so as to stride over its top, the gate insulating film 505 interposed between the gate electrode 522 and the projecting semiconductor layer 521L, and a source/drain area formed in the projecting semiconductor layer 521L on the opposite sides of the gate electrode.

The access transistor A₁ has a projecting semiconductor layer 511A, a gate electrode 513 extending on the opposite sides of the projecting semiconductor layer 511A so as to stride over its top, the gate insulating film 505 interposed between the gate electrode 513 and the projecting semiconductor layer 511A, and a source/drain area formed in the projecting semiconductor layer 511A on the opposite sides of the gate electrode. The other access transistor A₂ has a projecting semiconductor layer 521A, a gate electrode 523 extending on the opposite sides of the projecting semiconductor layer 521A so as to stride over its top, the gate insulating film 505 interposed between the gate electrode 523 and the projecting semiconductor layer 521A, and a source/drain area formed in the projecting semiconductor layer 521A on the opposite sides of the gate electrode (FIG. 6(a)).

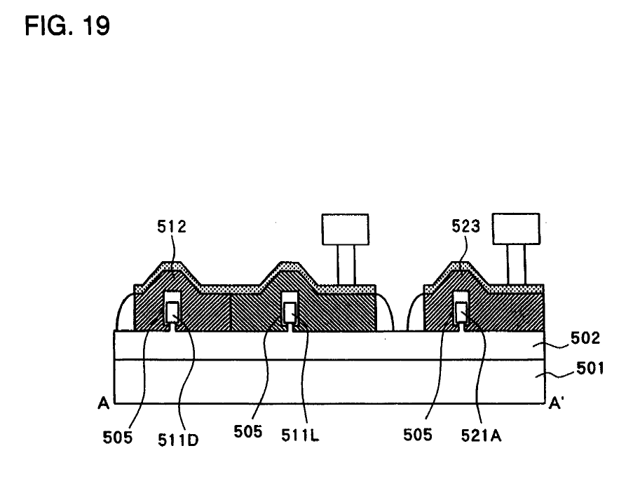

The transistors constituting the SRAM may have a structure shown in FIG. 19. FIG. 19 shows a sectional structure corresponding to FIG. 6(a) and in which a gate insulating film and a gate electrode are formed under a projecting semiconductor layer. This structure enables the bottom surface of the projecting semiconductor layer to be utilized as a channel, improving the ability to drive the transistors. This structure can be obtained by, for example, using the projecting semiconductor layer as a mask to isotropically etch the insulating layer 502 with fluoric acid or the like so that the insulating layer 502 is withdrawn under the projecting semiconductor layer, and then forming a gate insulating film and a gate electrode.

The projecting semiconductor layers constituting the transistors in the SRAM cell unit are provided so that their longitudinal direction (channel length direction) extends along a first direction (vertical direction of FIG. 5, that is, the direction of line C-C′). Between the adjacent SRAM cell units in the first direction, the projecting semiconductor layer of one of the corresponding transistors is placed on the center line of the projecting semiconductor layer of the other transistor extending along the first direction. This enables dense SRAM cell units to be formed, providing a SRAM structure which is easy to manufacture and which can be accurately formed.

The source area of the driving transistor D₁ is connected to a ground line (GND) via a contact plug 514c that connects to a pad semiconductor layer 514 integrated with the projecting semiconductor layer 511D. On the other hand, the drain area of the driving transistor D₁ is connected to the gate electrode 522 of the driving transistor D₂ and load transistor L₂ via a contact plug 519c that connects to a first node semiconductor layer 519 integrated with the projecting semiconductor layer 511D.

The source area of the load transistor L₁ is connected to a power supply line VDD (upper layer wire 601g) via a contact plug 515c that connects to a pad semiconductor layer 515 integrated with the projecting semiconductor layer 511L. On the other hand, the drain area of the load transistor L₁ is connected to the gate electrode 522 of the driving transistor D₂ and load transistor L₂ via the contact plug 519c that connects to the first node semiconductor layer 519 integrated with the projecting semiconductor layer 511L.

One of source and drain areas of the access transistor A₁ is connected to the bit line BL₁ (upper layer wire 601c) via a contact plug 516c that connects to a pad semiconductor layer 516 integrated with the projecting semiconductor layer 511A. The other of source and drain areas of the access transistor A₁ is connected to the gate electrode 522 of the driving transistor D₂ and load transistor L₂ via the contact plug 519c that connects to the first node semiconductor layer 519 integrated with the projecting semiconductor layer 511A.

The source area of the driving transistor D₂ is connected to the ground line GND (upper layer wire 601e) via a contact plug 524c that connects to a pad semiconductor layer 524 integrated with the projecting semiconductor layer 521D. On the other hand, the drain area of the driving transistor D₂ is connected to the gate electrode 512 of the driving transistor D₁ and load transistor L₁ via a contact plug 529c that connects to a second node semiconductor layer 529 integrated with the projecting semiconductor layer 521D.

The source area of the load transistor L₂ is connected to the power supply line VDD (upper layer wire 601d) via a contact plug 525c that connects to a pad semiconductor layer 525 integrated with the projecting semiconductor layer 521L. On the other hand, the drain area of the load transistor L₂ is connected to the gate electrode 512 of the driving transistor D₁ and load transistor L₁ via the contact plug 529c that connects to the second node semiconductor layer 529 integrated with the projecting semiconductor layer 521L.

One of source and drain areas of the access transistor A₂ is connected to the bit line BL₂ via a contact plug 526c that connects to a pad semiconductor layer 526 integrated with the projecting semiconductor layer 521A. The other of source and drain areas of the access transistor A₂ is connected to the gate electrode 512 of the driving transistor D₁ and load transistor L₁ via the contact plug 529c that connects to the second node semiconductor layer 529 integrated with the projecting semiconductor layer 521A.

The gate electrode of the driving transistor D₁ and load transistor L₁ is composed of a common gate wire 512 and connected to the second node semiconductor layer 529 via an upper layer wire 601a and a contact plug 517c that connects to a pad electrode 517 having a width larger than that (gate length L) of the gate electrode.

The gate electrode of the driving transistor D₂ and load transistor L₂ is composed of a common gate wire 522 and connected to the first node semiconductor layer 519 via an upper layer wire 601f and a contact plug 527c that connects to a pad electrode 527 having a width larger than that (gate length L) of the gate electrode.

The gate electrode 513 of the access transistor A₁ is placed so that the longitudinal center line of its gate electrode 513 aligns with the longitudinal center line of the gate wire 522. The gate electrode 513 is connected to the word line WL via a contact plug 518c that connects to a pad electrode 518 having a width larger than that (gate length) of the gate electrode.

The gate electrode 523 of the access transistor A₂ is placed so that the longitudinal center line of its gate electrode 523 aligns with the longitudinal center line of the gate wire 512. The gate electrode 513 is connected to the word line WL (upper layer wire 601b) via a contact plug 528c that connects to a pad electrode 528 having a width larger than that (gate length) of the gate electrode.

In the SRAM structure according to the present invention, the adjacent SRAM cell units are preferably in a mirror image relationship with respect to the cell unit boundary, which serves as a symmetry axis. That is, between the adjacent SRAM cell units, the semiconductor layer patterns constituting the projecting semiconductor layers, the wire patterns constituting the gate electrodes, and the layout of the contacts are preferably arranged line-symmetrically (mirror inversion) with respect to each of the four sides of the cell unit boundary, which serves as a symmetry axis.

The above configuration enables the formation of a dense SRAM structure which is easy to manufacture and which can be accurately formed. Moreover, for example, a layout configuration shown in FIG. 5 and described below makes it possible to provide a SRAM structure which is even easier to manufacture and which can be accurately formed.

The projecting semiconductor layers constituting the transistors in the SRAM cell unit are preferably arranged so that their longitudinal direction (channel length direction) extends along the first direction (vertical direction of FIG. 5, that is, the direction of line C-C′) and so that the intervals between the center lines of the projecting semiconductor layers which extend along the first direction are each an integral multiple of the minimum one of these intervals. These projecting semiconductor layers preferably have an equal width W (Va). Preferably, the minimum interval Rmin is the interval between the center line of projecting semiconductor layer of the load transistor L₁ and the center line of projecting semiconductor layer of the load transistor L₂. The center line of the projecting semiconductor layer is a line extending along the longitudinal direction (channel length direction) of the projecting semiconductor layer and passing though the middle point of width W (width parallel to the substrate plane and perpendicular to the channel length direction) of the projecting semiconductor layer.

In this SRAM structure, as for any of these projecting semiconductor layers, between the adjacent SRAM cell units in the first direction, the center lines of the projecting semiconductor layers of one and the other of the corresponding transistors are preferably arranged on one line. However, sufficient effects can be exerted if the deviation is at most 20% of the minimum interval, preferably at most 10% of the minimum interval.

In the SRAM cell unit shown in FIG. 5, the driving transistor D₁ has a semiconductor layer placed on the center line of projecting semiconductor layer of the access transistor A₁. The other driving transistor D₂ has a semiconductor layer placed on the center line of projecting semiconductor layer of the other access transistor A₂. The load transistor L₁ has a semiconductor layer adjacent to the projecting semiconductor layer of the driving transistor D₁. The other load transistor L₂ has a semiconductor layer adjacent to the projecting semiconductor layer of the other driving transistor D₂.

In the above SRAM unit, the driving transistors may be replaced with the load transistors. That is, the load transistor L₁ has a semiconductor layer placed on the center line of projecting semiconductor layer of the access transistor A₁. The other load transistor L₂ has a semiconductor layer placed on the center line of projecting semiconductor layer of the other access transistor A₂. The driving transistor D₁ has a semiconductor layer adjacent to the projecting semiconductor layer of the load transistor L₁. The other driving transistor D₂ has a semiconductor layer adjacent to the projecting semiconductor layer of the other load transistor L₂. The driving transistor D₁ and the other driving transistor D₂ may be configured so that the interval between the center lines of the projecting semiconductor layers of the driving transistor D₁ and the other driving transistor D₂ has the minimum interval.

In the SRAM cell unit according to the present invention, to ensure sufficient spaces for inter-gate separation and pn separation and a sufficient contact area, the layout configuration described below is preferably adopted, for example, as shown in FIG. 5.

(i) The interval between the center lines of the projecting semiconductor layers of the driving transistor D₁ and the adjacent load transistor L₁ and the interval between the center lines of the semiconductor layers of the other driving transistor D₂ and the adjacent other load transistor L₂ are each at least double the minimum interval Rmin.

(ii) Between the adjacent SRAM cell units in a second direction (lateral direction of FIG. 5; this will apply to the following description) perpendicular to the first direction, the interval between the center lines of the semiconductor layers of one and the other of the transistors is at least double the minimum interval Rmin.

Too large values of these intervals increase the area of the cell unit. Each of these intervals is thus preferably at most three times as large as the minimum interval Rmin.

Requirement (i) ensures sufficient spaces (between 517 and 523 and between 513 and 527) for inter-gate separation and sufficient spaces (near 519 and near 529) for pn separation. Requirement (ii) ensures sufficient spaces (near 518 and near 528) for contact with the word lines.

Further, with the SRAM cell unit according to the present invention, the layout of the contacts described below and, for example, shown in FIG. 5 serves to increase the density and to provide a SRAM structure that is easy to manufacture.

That is, the ground line contact 514c connected to the source area of the driving transistor D₁, the power source line contact 515c connected to the source area of the load transistor L₁, and the bit line contact 526c connected to the source/drain area of the access transistor A₂ are arranged on one line on one of the cell unit boundaries extending along the second direction. The ground line contact 524c connected to the source area of the other driving transistor D₂, the power source line contact 525c connected to the source area of the other load transistor L₂, and the bit line contact 516c connected to the source/drain area of the other access transistor A₁ are arranged on one line on the other cell unit boundary extending along the second direction.

In the SRAM structure of the present embodiment, shown in FIGS. 5 to 7, the projecting semiconductor layers of the transistors are provided on the insulating layer 502. A structure described below is available for this configuration. That is, for example, as shown in FIG. 5, in the SRAM cell unit, the driving transistor D₁ has a semiconductor layer 511D integrated with the semiconductor layer 511A of the access transistor A₁ and the semiconductor layer 511L of the load transistor L₁. The other driving transistor D₂ has a semiconductor layer 521D integrated with the semiconductor layer 521A of the other access transistor A2 and the semiconductor layer 521L of the other load transistor L₂.

Moreover, this configuration may have the first node semiconductor layer 519 (FIG. 7) integrated with the semiconductor layer 511D of the driving transistor D₁, the semiconductor layer 511L of the load transistor L₁ and the semiconductor layer 511A of the access transistor A₁, and having a pn junction 519j of a p-type area and an n-type area; and the second node semiconductor layer 529 integrated with the semiconductor layer 521D of the driving transistor D₂, the semiconductor layer 521L of the load transistor L₂ and the semiconductor layer 521A of the access transistor A₂, and having a pn junction 529j of a p-type area and an n-type area.

According to the configuration, the semiconductor layer constituting the projecting semiconductor layer of each transistor is provided on the insulating layer. Thus, directly joining the p- and n-type areas together enables the drain of the driving transistor to be connected to the drain of the load transistor. The p-type area and the n-type area can be electrically short circuited by the silicide layer 509. This enables a reduction in the SRAM cell unit area. In contrast, a structure having a well area under the semiconductor layer requires an insulating isolation area to be interposed between the p-type area and the n-type area. This correspondingly increases the area. The above structure eliminates such an isolating insulation area, enabling an increase in density.

Further, in this structure, the node contact 519c connected to the upper layer wire 601h is connected to the first node semiconductor layer 519. The second node contact 529c connected to the upper layer wire is connected to the second node semiconductor layer 529. The first and second node semiconductor layers also function as contact pad layers. This configuration thus makes it possible to ensure a sufficient node contact area while increasing the density.

[Manufacturing Method]

Now, description will be given of a method for manufacturing a SRAM structure as shown in FIGS. 5 to 7.

First, an SOI substrate is prepared which has a buried insulating film (base insulating film) made of SiO₂ on a silicon substrate and a semiconductor layer made of single crystal silicon provided on the buried insulating film. Then, a sacrifice oxide film is formed on the semiconductor layer of the SOI substrate. Impurities are ion implanted in the semiconductor layer via the sacrifice oxide film to form a channel area. The sacrifice oxide film is subsequently removed. A cap insulating film is then formed on the semiconductor layer. Doping impurities to form a channel area can be carried out by oblique ion implantation, Halo implantation or the like following patterning of the semiconductor layer.

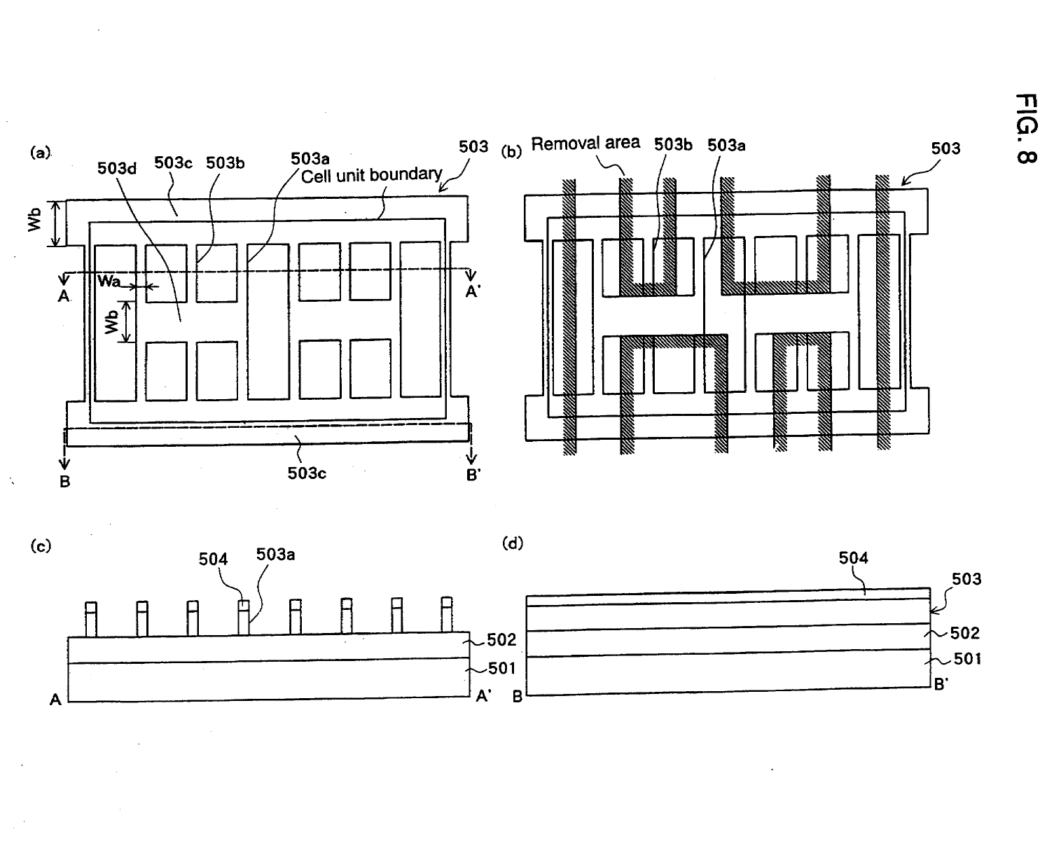

Then, the semiconductor layer and the cap insulating film formed on the semiconductor layer are patterned by photolithography and dry etching to form a semiconductor layer pattern having a striped pattern portion in which elongate semiconductor layers are arranged at equal intervals. This state is shown in FIG. 8. FIGS. 8(a) and 8(b) are plan views. FIG. 8(c) is a sectional view taken along line A-A′. FIG. 8(d) is a sectional view taken along line B-B′. Areas enclosed by oblique lines show areas from which the semiconductor layer is removed in a subsequent step. Reference numeral 501 in the figures denotes a semiconductor substrate. Reference numeral 502 denotes a buried insulating film. Reference numeral 503 denotes a semiconductor layer. Reference numerals 503a and 503b denote elongate semiconductor layers. Reference numeral 504 denotes a cap insulating film.

The elongate semiconductor layer 503a constitutes a projecting semiconductor layer of a FIN type FET. The elongate semiconductor layer 503b is a dummy semiconductor layer that is removed during a subsequent step. The semiconductor layer patterns 503, each including the elongate semiconductor layers 503a and 503b, are formed to be line symmetric (mirror inversion) with respect to each of four sides of the cell unit boundary corresponding to the SRAM cell unit boundary, which side serves as a symmetry axis. Formation of such high periodic patterns makes it possible to uniformly and accurately form fine patterns in this pattern area.

Band-like semiconductor layer portions 503c and 503d orthogonal to the elongate semiconductor layers 503a and 503b are partly removed during a subsequent step so that the remaining portions constitute pad semiconductor layers that contact to contact plugs. The band-like semiconductor layer portions 503c are formed into pad semiconductor layers for a ground line contact, a power source line contact, and bit line contacts. The band-like semiconductor layer portions 503d are formed into pad semiconductor layers for storage node contacts. The width Wb of each of these band-like semiconductor layers in the first direction is preferably set larger than that Wa of the elongate semiconductor layer in the second direction.

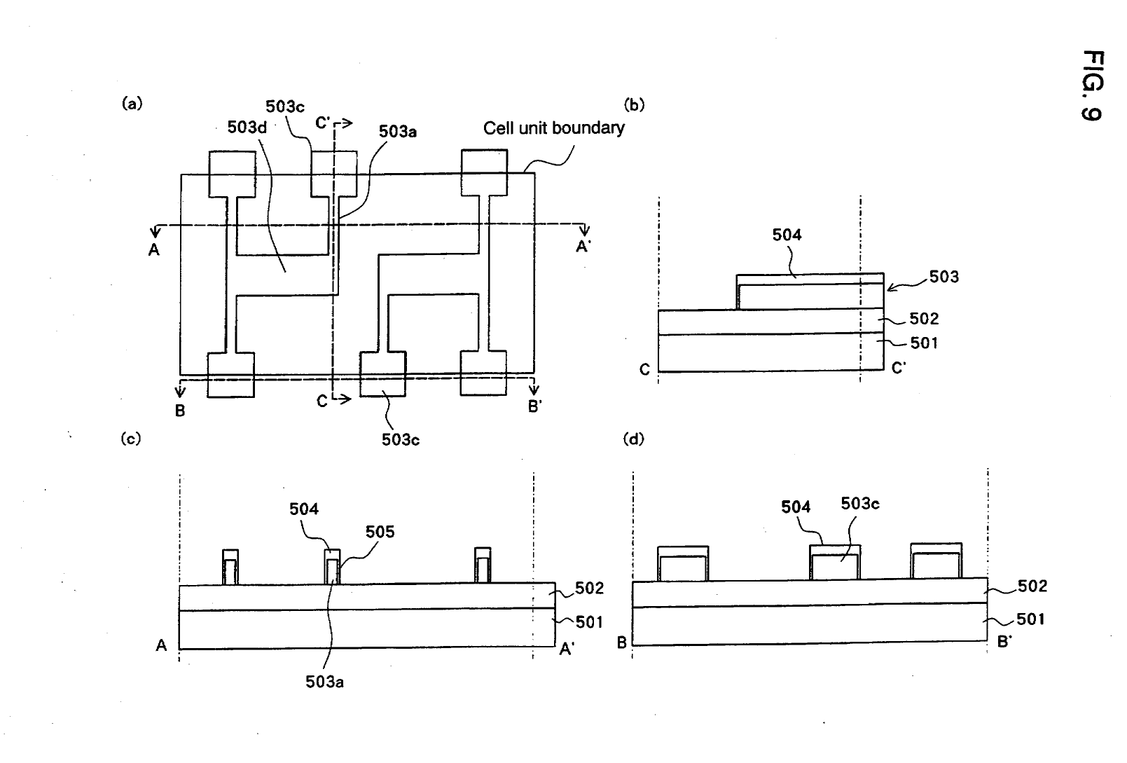

Then, the unwanted portions of the semiconductor layer pattern are removed by lithography and dry etching. A gate oxide film 505 is formed on the sides of the elongate semiconductor layer by a thermal oxidation process or the like. This state is shown in FIG. 9. FIG. 9(a) is a plan view. FIG. 9(b) is a sectional view taken along line C-C′. FIG. 9(c) is a sectional view taken along line A-A′. FIG. 9(d) is a sectional view taken along line B-B′. Vertical broken lines in the right and left of each of FIGS. 9(b) to 9(d) indicate cell unit boundaries.

The remaining elongate semiconductor layer portions 503a constitute the projecting semiconductor layers of the FIN type FETs. The remaining band-like semiconductor layer portions 503c constitute the pad semiconductor layers for the ground line contact, power source line contact, and bit line contact. The remaining band-like semiconductor layer portions 503d constitute the pad semiconductor layers for the storage node contacts.

Then, a gate electrode material is deposited and formed into gate electrodes by lithography and dry etching. For example, polysilicon is deposited and lithography and ion implantation are used to dope n-type impurities (phosphorous, arsenic, or the like) into the nMOS area and p-type impurities (boron or the like) into the pMOS area. Gate wires are then formed by lithography and dry etching. This makes it possible to form gates of n-type polysilicon in the nMOS area and gates of p-type polysilicon in the pMOS area.

Then, impurities are doped into the elongate semiconductor layers through their sides by ion implantation oblique to the substrate plane, to form an extension dope area. On this occasion, lithography is used to dope the n-type impurities (phosphorous, arsenic, or the like) into the nMOS area and the p-type impurities (boron or the like) into the pMOS area. Halo implantation may be carried out before or after the ion implantation for forming the extension dope area; the Halo implantation involves ion implanting impurities of a conductivity type opposite to that of the extension dope area.

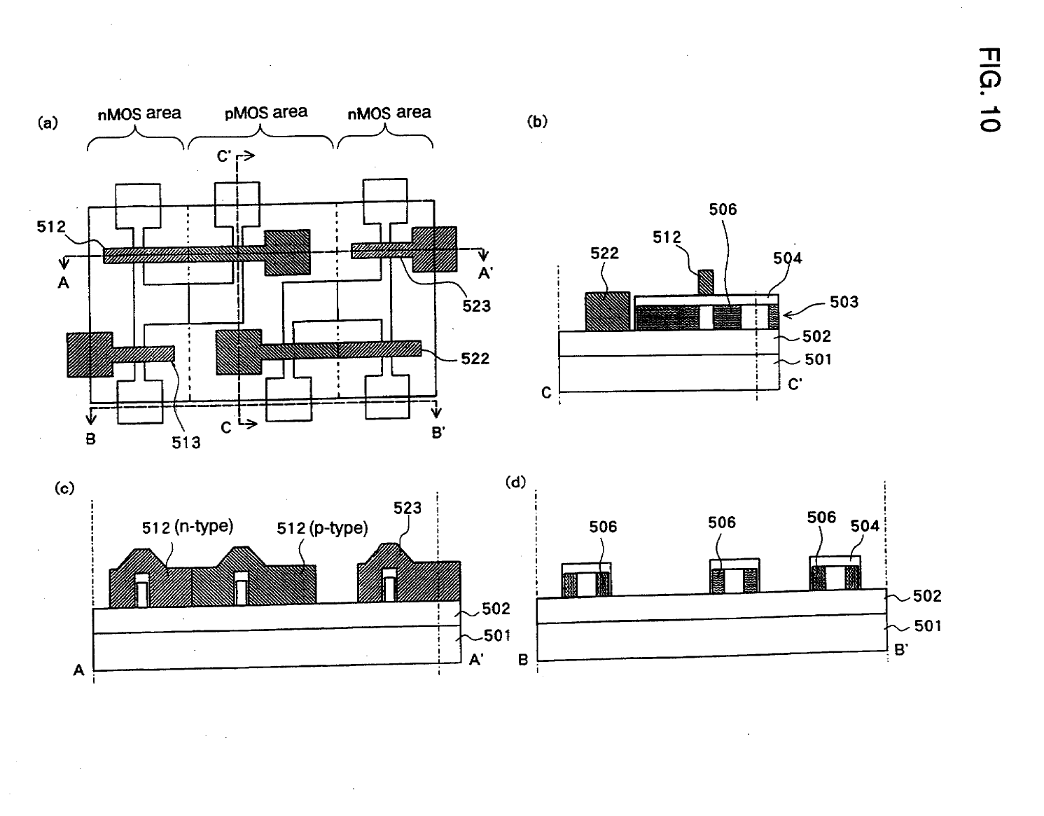

This state is shown in FIG. 10. FIG. 10(a) is a plan view. FIG. 10(b) is a sectional view taken along line C-C′. FIG. 10(c) is a sectional view taken along line A-A′. FIG. 10(d) is a sectional view taken along line B-B′. Vertical broken lines in the right and left of each of FIGS. 10(b) to 10(d) indicate cell unit boundaries. Reference numerals 512, 513, 522, and 523 denote gate wires. Reference numeral 506 denotes an extension dope area.

Then, an insulating film is deposited all over the surface. The insulating film is then etched back by anisotropic etching to form a side wall insulating film. At this time, the cap insulating film 504 is also etched away to expose the top surface of the semiconductor layer except for the side wall insulating film.

Then, ions are implanted perpendicularly to the substrate plane to form a source/drain diffusion area. On this occasion, lithography is used to dope the n-type impurities (phosphorous, arsenic, or the like) into the nMOS area and the p-type impurities (boron or the like) into the pMOS area. The extension dope area, which does not overlap the source/drain diffusion area, constitutes an extension area. What is called an LDD (Lightly Doped Drain) structure is formed.

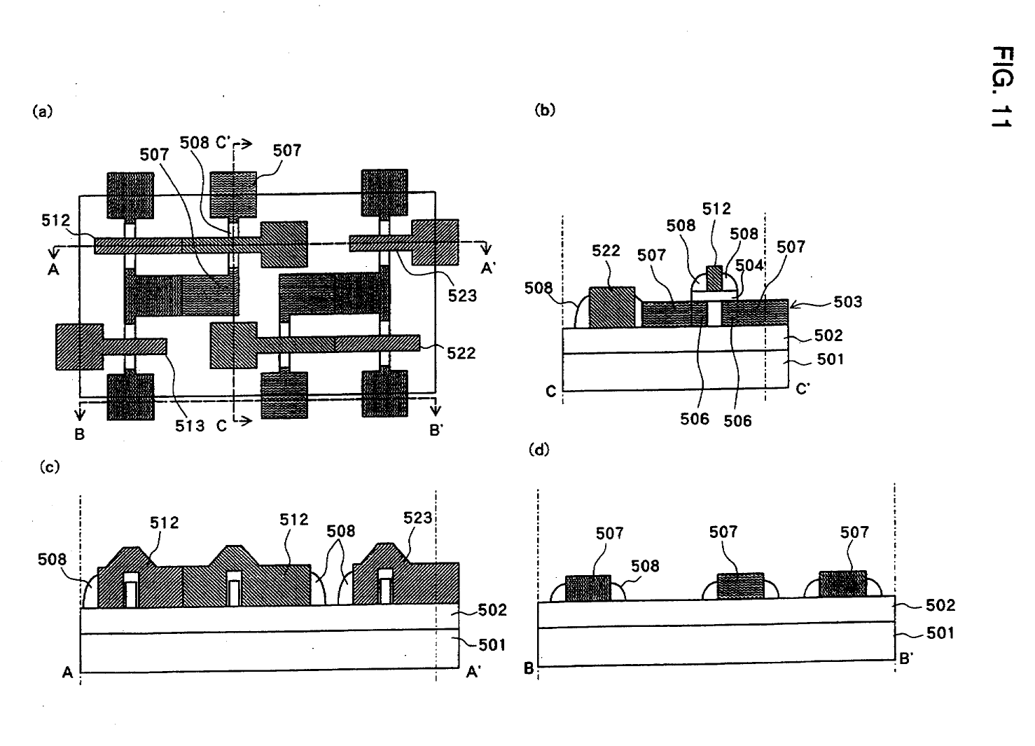

This state is shown in FIG. 11. FIG. 11(a) is a plan view. FIG. 11(b) is a sectional view taken along line C-C′. FIG. 11(c) is a sectional view taken along line A-A′. FIG. 11(d) is a sectional view taken along line B-B′. Vertical broken lines in the right and left of each of FIGS. 11(b) to 11(d) indicate cell unit boundaries. Reference numeral 508 denotes a side wall insulating film, Reference numeral 506 denotes an extension area. Reference numeral 507 denotes a source/drain area. FIG. 11(a) shows only a part of the side wall insulating film 508 which overlaps the semiconductor projecting area.

Then, what is called a salicide process is used to form a silicide layer 509 of nickel silicide on the source/drain diffusion areas and gate wires (gate electrodes). A predetermined SRAM structure is subsequently obtained by executing twice a series of the step of forming an interlayer insulating film, the step of forming contact plugs, and the step of forming wires. This state is shown in FIGS. 6 and 7, described above. These figures show only one layer of upper layer wiring. However, the upper layer wiring actually comprises a plurality of layers three-dimensionally crossing one another in both vertical and horizontal directions via interlayer insulating films.

[Another Example of a Semiconductor Layer Pattern]

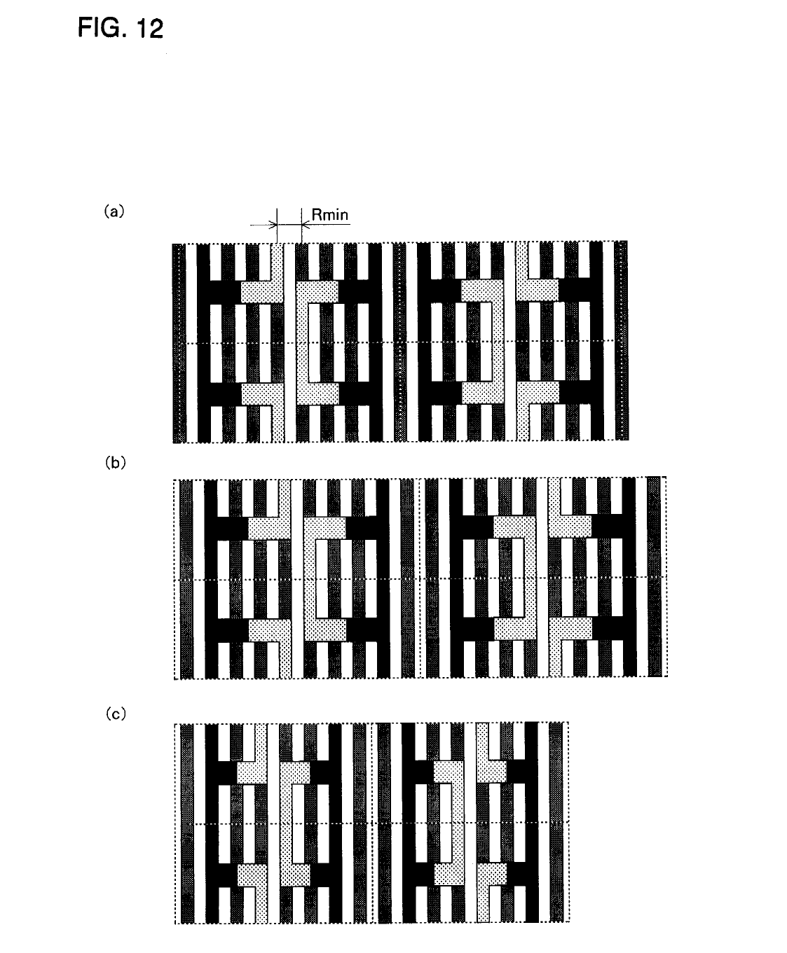

FIGS. 12(a) to 12(c) show another example of the semiconductor layer pattern corresponding to FIG. 8(a). FIG. 8(a) shows an area corresponding to one SRAM cell unit. However, FIGS. 12(a) to 12(c) show an area corresponding to 2×2, that is, a total of four SRAM cell units. Dotted lines in the figures show cell unit boundaries. Semiconductor layer patterns in black portions and in dotted portions are to be left after the subsequent removal step. Impurities are ion implanted so that the semiconductor layer patterns in the black portions will be of the n type, while the semiconductor layer patterns in the dotted portions will be of the p type.

In the semiconductor layer pattern shown in FIG. 12(a), the two elongate semiconductor layers are removed which are located between the elongate semiconductor layer constituting the driving transistor and the elongate semiconductor layer constituting the load transistor. As a result, the distance between the center lines of the elongate semiconductor layers constituting the driving transistor and the load transistor is three times as large as the minimum interval Rmin. Further, between the adjacent unit areas in the second direction (lateral direction of the figure), the one elongate semiconductor layer between the elongate semiconductor layers constituting the adjacent access transistors is removed. As a result, the distance between the center lines of the elongate semiconductor layers constituting the adjacent access transistors is double the minimum interval Rmin.

In the semiconductor layer pattern shown in FIG. 12(b), the two elongate semiconductor layers are removed which are located between the elongate semiconductor layer constituting the driving transistor and the elongate semiconductor layer constituting the load transistor. As a result, the distance between the center lines of the elongate semiconductor layers constituting the driving transistor and the load transistor is three times as large as the minimum interval Rmin. Further, between the adjacent unit areas in the second direction (lateral direction of the figure), the two elongate semiconductor layers between the elongate semiconductor layers constituting the adjacent access transistors are removed. As a result, the distance between the center lines of the elongate semiconductor layers constituting the adjacent access transistors is three times as large as the minimum interval Rmin.

In the semiconductor layer pattern shown in FIG. 12(c), the one elongate semiconductor layer is removed which is located between the elongate semiconductor layer constituting the driving transistor and the elongate semiconductor layer constituting the load transistor. As a result, the distance between the center lines of the elongate semiconductor layers constituting the driving transistor and the load transistor is double the minimum interval Rmin. Further, between the adjacent unit areas in the second direction (lateral direction of the figure), the two elongate semiconductor layers between the elongate semiconductor layers constituting the adjacent access transistors are removed. As a result, the distance between the center lines of the elongate semiconductor layers constituting the adjacent access transistors is three times as large as the minimum interval Rmin,

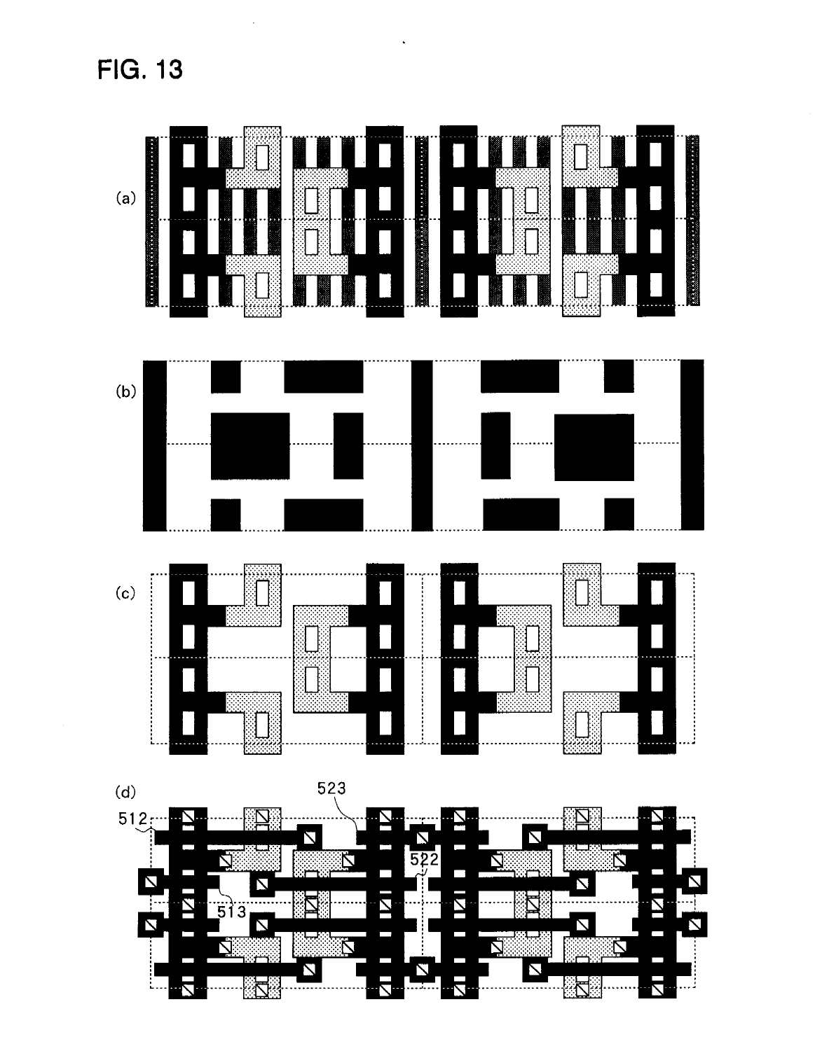

FIGS. 13(a) to 13(d) show an example in which a FIN type FET having what is called a multi-structure is applied to a SRAM; in the multi-structure, one FIN type transistor has a plurality of projecting semiconductor layers. In this example, each of the driving transistor, load transistor, and access transistor has two projecting semiconductor layers.

FIG. 13(a) shows another example of the semiconductor layer pattern corresponding to FIG. 8(a). FIG. 8(a) shows an area corresponding to one SRAM cell unit. However, FIG. 13(a) shows an area corresponding to 2×2, that is, a total of four SRAM cell units. Dotted lines in the figures show cell unit boundaries. Semiconductor layer patterns in black portions and in dotted portions are to be left after the subsequent removal step. Impurities are ion implanted so that the semiconductor layer patterns in the black portions will be of the n type, while the semiconductor layer patterns in the dotted portions will be of the p type. FIG. 13(b) shows a pattern of areas to be removed from the semiconductor layer pattern. Unwanted portions of the semiconductor layer pattern are removed to form a semiconductor layer pattern shown in FIG. 13(c). A SRAM structure shown in FIG. 13(d) can then be formed through a process similar to the above manufacturing method.

[Another Example (1) of the SRAM Element Structure]

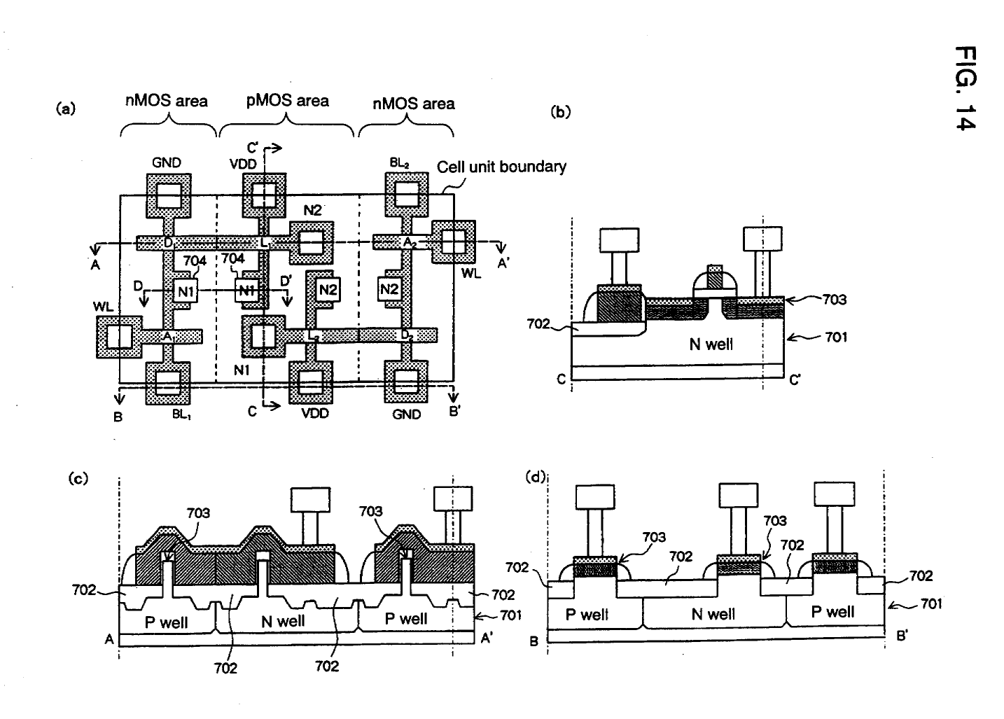

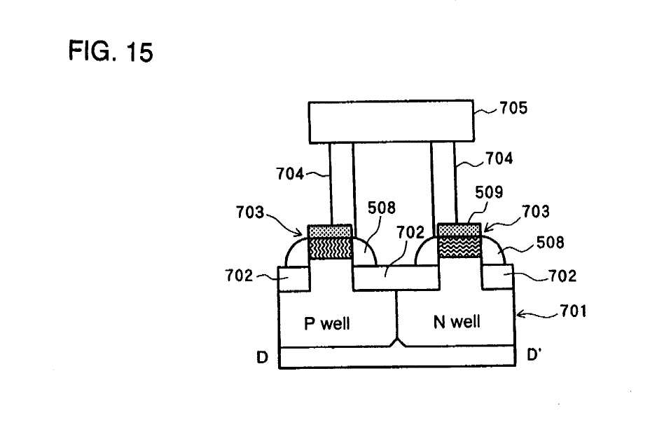

FIGS. 14 and 15 show other element structures of the SRAM cell unit. FIG. 14(a) is a plan view. FIG. 14(b) is a sectional view taken along line C-C′. FIG. 14(c) is a sectional view taken along line A-A′. FIG. 14(d) is a sectional view taken along line B-B′. FIG. 15 is a sectional view taken along line D-D′. The side wall insulating films 508 are omitted in FIG. 14(a). Vertical broken lines in the right and left of each of FIGS. 14(b) to 14(d) indicate cell unit boundaries.

In the present embodiment, a bulk semiconductor substrate is used in place of the SOI substrate. The projecting semiconductor layer of the FIN type FET is made of a part of the semiconductor substrate. The projecting semiconductor layer projects upward from the surface of an isolating insulation film provided on the semiconductor substrate. Further, the semiconductor layer portion constituting the drain of the driving transistor is separated from the semiconductor layer portion constituting the drain of the load transistor. The storage node contact is connected to each of the semiconductor layer portions. Except for these points, the structure of the present embodiment is similar to the SRAM structure shown in FIGS. 5 and 6, described above.

A semiconductor pattern 703 in the present embodiment is integrated with a bulk semiconductor substrate 701 and is composed of a portion thereof as shown in FIGS. 14(b) and 14(c). The semiconductor layer pattern 703 projects upward from the surface of an isolating insulation film 702 provided on the semiconductor substrate 701. The periphery of the projecting portion is surrounded by the isolating insulation film. That is, the isolating insulation film 702 is provided on the semiconductor substrate except for the projecting semiconductor layer patterns. In the semiconductor substrate area under the semiconductor layer pattern and isolating insulation film, P wells are provided in the nMOS area, whereas N wells are provided in the pMOS area.

In the contact structure of the storage node according to the present embodiment, as shown in FIGS. 14(a) and 15, contact plugs 704 are connected to the semiconductor layer (n type) constituting the drain of the driving transistor and the semiconductor layer (p type) constituting the drain of the load transistor. The contact plugs 704 are connected together via upper wiring 705. When a pn junction is formed in the semiconductor layer to directly join both drains as shown in FIGS. 5 and 7, the diffusion areas in the projecting semiconductor layers and the underlayer wells are short circuited. Thus, in the present embodiment, the n- and p-type semiconductor layers constituting the drain are isolated from each other by the isolating insulation film 702. The isolated semiconductor layers are connected by the upper layer wiring 705 via the contact plugs 704 that connect to the semiconductor layers.

The above configuration can be manufactured, for example, as described below.

A semiconductor substrate, for example, a silicon substrate is prepared in which a P well and an N well are provided in predetermined areas. Ions are implanted in the silicon substrate as required to form a channel area. A cap insulating film is formed all over the surface of the silicon substrate.

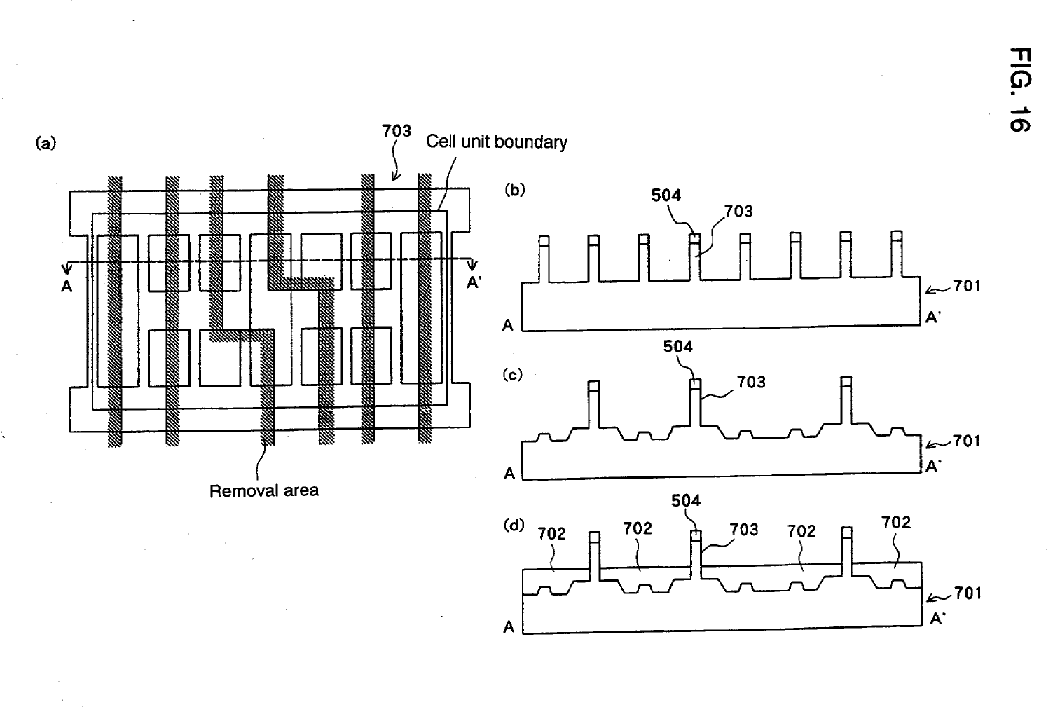

The silicon substrate and the cap insulating film formed on the silicon substrate are patterned by photolithography and dry etching to form a semiconductor layer pattern having a striped pattern in which elongate semiconductor layers are arranged at equal intervals. This state is shown in FIGS. 16(a) and 16(b). FIG. 16(a) is a plan view. FIG. 16(b) is a sectional view taken along line A-A′. Areas enclosed by oblique lines in FIG. 16(a) show areas from which the semiconductor layer pattern is to be removed in the subsequent step.

Unwanted portions of the semiconductor layer pattern are then removed by lithography and dry etching. The sectional view in FIG. 16(c) taken along line A-A′ shows how the unwanted portions are removed.

Then, an insulating film is deposited all over the surface so as to bury the remaining semiconductor layer pattern. The surface of the insulating film is flattened by CMP (Chemical Mechanical Polishing). The insulating film is subsequently etched back to expose the top of the semiconductor layer pattern 703. An isolating insulation film 702 is formed around the periphery of the semiconductor layer pattern. The sectional view in FIG. 16(d) taken along line A-A′ shows how the isolating insulation film 702 is formed.

Subsequently, the SRAM structure of the present embodiment can be produced in a manner similar to that described above except for the steps relating to the contact structure of the storage node.

[Another Example (2) of the SRAM Element Structure]

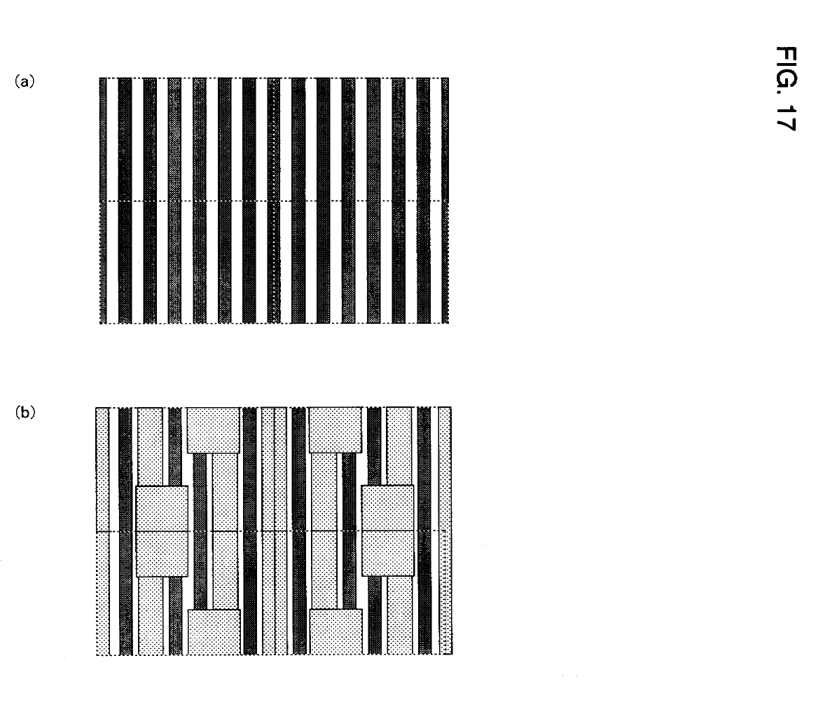

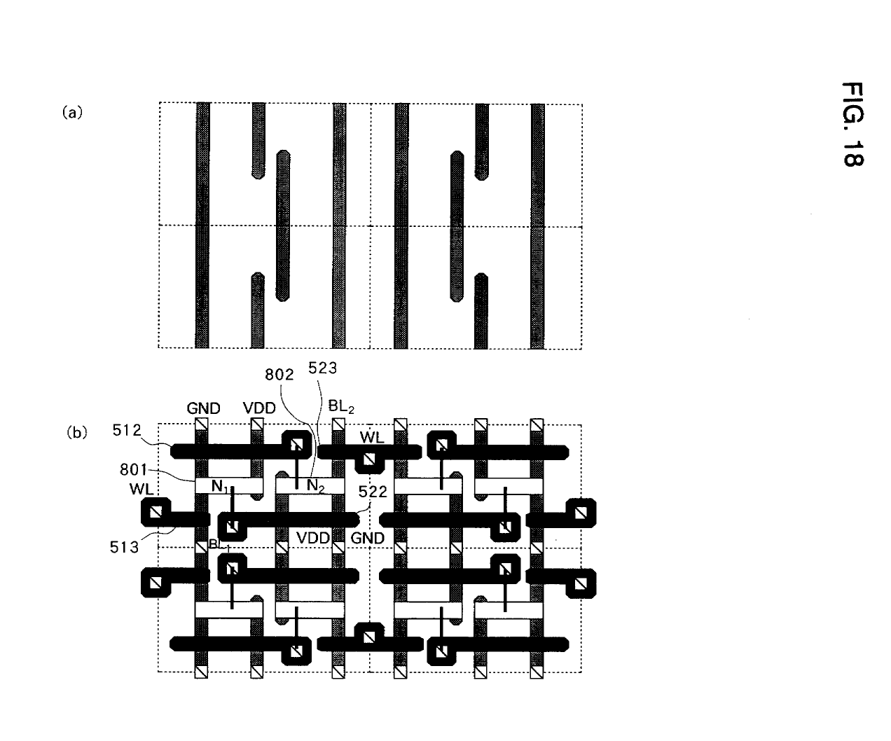

FIGS. 17 and 18 show another example of the SRAM element structure. These figures show an area corresponding to 2×2, that is, a total of four SRAM cell units. Dotted lines in the figures indicate cell unit boundaries.

FIG. 17(a) shows another example (line and space pattern) of the semiconductor layer pattern corresponding to FIG. 8(a). This semiconductor layer pattern has no pattern in the second direction which crosses the elongate semiconductor layer extending in the first direction. This semiconductor layer pattern is thus composed of a striped pattern in which elongate semiconductor layers are arranged at equal intervals all over the SRAM formed area.

FIG. 17(b) shows the semiconductor layer pattern shown in FIG. 17(a) which is overlapped by a pattern showing areas from which the semiconductor layers are to be removed. Unwanted portions of the semiconductor pattern are removed to form the semiconductor layer pattern shown in FIG. 18(a). The SRAM structure shown in FIG. 18(b) can be produced in a manner similar to that described above.

In the SRAM structure shown in FIG. 18(b), reference numeral 801 denotes a buried conductor wire that connects the drain of the driving transistor D₁ and the drain of the load transistor L₁ together. Reference numeral 802 denotes a buried conductor wire that connects the drain of the driving transistor D₂ and the drain of the load transistor L₂ together. These buried conductor wires are connected to the upper layer wire to serve as the contact plug for the storage node. These buried conductor wires can be formed by forming an hole like a groove in the interlayer insulating film along the second direction, exposing, in the hole, semiconductor layers to be connected together, and burying a conductive material in the hole. Alternatively, a structure can be used in which a contact plug is connected to each of the semiconductor layer constituting the drain of the driving transistor and the semiconductor layer constituting the drain of the load transistor so that the drains can be connected together by the upper layer wire via these contact plugs as shown in FIGS. 14(a) and 15.

1. A semiconductor device having SRAM cell units each comprising a pair of a first driving transistor and a second driving transistor, a pair of a first load transistor and a second load transistor, and a pair of a first access transistor and a second access transistor, wherein:
each of the transistors comprises a semiconductor layer projecting upward from a substrate plane, a gate electrode extending on opposite sides of the semiconductor layer so as to stride over a top of the semiconductor layer, a gate insulting film interposed between the gate electrode and the semiconductor layer, and a pair of source/drain areas formed in the semiconductor layer;
a longitudinal direction of each semiconductor layer extends along a first direction; and
between the adjacent SRAM cell units in the first direction, the semiconductor layer in one of the corresponding transistors is located on a center line of the semiconductor layer in the other transistor which center line extends along the first direction.

2. A semiconductor device having SRAM cell units each comprising a pair of a first driving transistor and a second driving transistor, a pair of a first load transistor and a second load transistor, and a pair of a first access transistor and a second access transistor, wherein:
each of the transistors comprises a semiconductor layer projecting upward from a substrate plane, a gate electrode extending on opposite sides of the semiconductor layer so as to stride over a top of the semiconductor layer, a gate insulting film interposed between the gate electrode and the semiconductor layer, and a pair of source/drain areas formed in the semiconductor layer;
the semiconductor layers are arranged so that a longitudinal direction of each semiconductor layer extends along a first direction and so that intervals between center lines of the semiconductor layers which center lines extend along the first direction are each an integral multiple of the minimum one of the intervals;
the semiconductor layers have an equal width in a second direction which is parallel to the substrate plane and perpendicular to the first direction; and
between the adjacent SRAM cell units in the first direction, the semiconductor layer in one of the corresponding transistors is located on a center line of the semiconductor layer in the other transistor which center line extends along the first direction.

3. The semiconductor device according to claim 2, wherein in the SRAM cell unit, the first driving transistor comprises a semiconductor layer placed on a center line of the semiconductor layer of the first access transistor which center line extends along the first direction, and the second driving transistor has a semiconductor layer placed on a center line of the semiconductor layer of the second access transistor which center line extends along the first direction;
the first load transistor comprises a semiconductor layer adjacent to the semiconductor layer of the first driving transistor, and the second load transistor has a semiconductor layer adjacent to the semiconductor layer of the second driving transistor; and
the first load transistor and the second load transistor are arranged so that the interval between the center line of the semiconductor layer of the first load transistor and the center line of the semiconductor layer of the second load transistor is equal to the minimum interval.

4. The semiconductor device according to claim 2, wherein in the SRAM cell unit,
the first load transistor comprises a semiconductor layer placed on a center line of the semiconductor layer of the first access transistor which center line extends along the first direction, and the second load transistor has a semiconductor layer placed on a center line of the semiconductor layer of the second access transistor which center line extends along the first direction;
the first driving transistor comprises a semiconductor layer adjacent to the semiconductor layer of the first load transistor, and the second driving transistor has a semiconductor layer adjacent to the semiconductor layer of the second load transistor; and
the first driving transistor and the second driving transistor are arranged so that the interval between the center line of the semiconductor layer of the first driving transistor and the center line of the semiconductor layer of the second driving transistor is equal to the minimum interval.

5. The semiconductor device according to claim 2, 3, or 4, wherein
the interval between the center lines extending along the first direction of the semiconductor layers of the first driving transistor and the first load transistor which are adjacent to each other is at least double the minimum interval; and
the interval between the center lines extending along the first direction of the semiconductor layers of the second driving transistor and the second load transistor which are adjacent to each other is at least double the minimum interval.

6. The semiconductor device according to any one of claims 2 to 5, wherein between the adjacent SRAM cell units in the second direction, the access transistors of one and the other of the SRAM cell units are arranged adjacent to each other, and the interval between the center lines extending along the first direction of the semiconductor layers of one and the other of the access transistors is at least double the minimum interval.

7. The semiconductor device according to any one of claims 2 to 6, wherein each of the semiconductor layers constituting the transistors in the SRAM cell unit is made of a semiconductor layer provided on an insulating layer.

8. The semiconductor device according to claim 7, wherein in the SRAM cell unit, the first driving transistor has a semiconductor layer integrated with the semiconductor layer of the first access transistor and the semiconductor layer of the first load transistor, and the second driving transistor has a semiconductor layer integrated with the semiconductor layer of the second access transistor and the semiconductor layer of the second load transistor.

9. The semiconductor device according to claim 7, wherein
the SRAM cell unit has, on the insulating layer, a first semiconductor layer area integrated with the semiconductor layer of the first driving transistor, the semiconductor layer of the first load transistor and the semiconductor layer of the first access transistor and having a junction between an area of a first conductivity type and an area of a second conductivity type together, and a second semiconductor layer area integrated with the semiconductor layer of the second driving transistor, the semiconductor layer of the second load transistor and the semiconductor layer of the second access transistor and having a junction between an area of the first conductivity type and an area of the second conductivity type together; and
a first node contact connected to a drain area of the first driving transistor and to a drain area of the first load transistor is connected to the first semiconductor layer area, and a second node contact connected to a drain area of the second driving transistor and to a drain area of the second load transistor is connected to the second semiconductor layer area.

10. The semiconductor device according to claim 1, wherein in the SRAM cell unit,
each of the semiconductor layers constituting the transistors is made of a semiconductor layer provided on an insulating layer; and
the first driving transistor has a semiconductor layer integrated with the semiconductor layer of the first access transistor and the semiconductor layer of the first load transistor, and the second driving transistor has a semiconductor layer integrated with the semiconductor layer of the second access transistor and the semiconductor layer of the second load transistor.

11. The semiconductor device according to claim 1, wherein in the SRAM cell unit,
each of the semiconductor layers constituting the transistors is made of a semiconductor layer provided on an insulating layer;
the SRAM cell unit has, on the insulating layer, a first semiconductor layer area integrated with the semiconductor layer of the first driving transistor, the semiconductor layer of the first load transistor and the semiconductor layer of the first access transistor and having a junction between an area of the first conductivity type and an area of the second conductivity type together, and a second semiconductor layer area integrated with the semiconductor layer of the second driving transistor, the semiconductor layer of the second load transistor and the semiconductor layer of the second access transistor and having a junction between an area of the first conductivity type and an area of the second conductivity type together; and
the first node contact connected to a drain area of the first driving transistor and to a drain area of the first load transistor is connected to the first semiconductor layer area, and the second node contact connected to a drain area of the second driving transistor and to a drain area of the second load transistor is connected to the second semiconductor layer area.

12. The semiconductor device according to any one of claims 1 to 6, wherein each of the semiconductor layers constituting the transistors in the SRAM cell unit is formed of a part of a semiconductor substrate and projects from a top surface of an isolating insulating film on the semiconductor substrate.

13. The semiconductor device according to any one of claims 1 to 12, wherein in the SRAM cell unit,
the gate electrode of the first driving transistor and the gate electrode of the first load transistor are formed of a first wire extending along the second direction perpendicular to the first direction, and the gate electrode of the second driving transistor and the gate electrode of the second load transistor are formed of a second wire extending along the second direction; and
the gate electrode of the first access transistor is formed of a third wire placed on a center line of the second wire extending along the second direction and the gate electrode of the second access transistor is formed of a fourth wire placed on a center line of the first wire extending along the second direction.

14. The semiconductor device according to any one of claims 1 to 13, wherein a ground line contact connected to the source area of the first driving transistor, a power source line contact connected to the source area of the first load transistor, and a bit line contact connected to the source/drain area of the second access transistor are arranged on one line at one of cell unit boundaries extending along the second direction; and
a ground line contact connected to the source area of the second driving transistor, a power source line contact connected to the source area of the second load transistor, and a bit line contact connected to the source/drain area of the first access transistor are arranged on one line at the other cell unit boundary extending along the second direction.

15. The semiconductor device according to claim 14, wherein each of the ground line contacts, the power source line contacts, and the bit line contacts has a width in the second direction which is larger than the width in the second direction of the semiconductor layer under the gate electrode, and is connected to a pad semiconductor layer integrated with the semiconductor layer.

16. The semiconductor device according to any one of claims 1 to 15, wherein the adjacent SRAM cell units are in a mirror image relationship with respect to the cell unit boundary, which serves as a symmetry axis.

17. A method for manufacturing a semiconductor device having SRAM cell units each comprising a pair of a first driving transistor and a second driving transistor, a pair of a first load transistor and a second load transistor, and a pair of a first access transistor and a second access transistor, each of the transistors having a semiconductor layer projecting upward from a substrate plane, a gate electrode extending on opposite sides of the semiconductor layer so as to stride over a top of the semiconductor layer, a gate insulting film interposed between the gate electrode and the semiconductor layer, and a pair of source/drain areas formed in the semiconductor layer, the method comprising the steps of:
pattering a semiconductor layer to form a semiconductor pattern having a striped pattern in which elongate semiconductor layers extending in a first direction and having an equal width in a second direction perpendicular to the first direction are arranged at equal intervals;
removing a part of the striped pattern;
forming a gate insulating film on sides of the remaining elongate semiconductor layers;
depositing a gate electrode material and pattering the gate electrode material deposited film to form gate electrodes each extending on opposite surfaces of the elongate semiconductor layer along the second direction so as to stride over a top of the elongate semiconductor layer; and
doping impurities into each elongate semiconductor layer to form source/drain areas.

18. The method for manufacturing a semiconductor device according to claim 17, wherein the semiconductor layer patterns are line symmetric with respect to each of four sides of a rectangular unit boundary corresponding to a SRAM cell unit boundary, which serves as a symmetry axis.

19. The method for manufacturing a semiconductor device according to claim 17 or 18, wherein
in the step of forming the semiconductor layer pattern, a band-like pattern is formed which crosses the elongate semiconductor layer and which has a width in the first direction which is larger than the width in the second direction of the elongate semiconductor layer; and
in the step of removing a part of the striped pattern, a part of the band-like pattern is also removed to form a pad semiconductor layer having a width in the second direction which is larger than the width in the second direction of the elongate semiconductor layer, and a contact connected with upper layer wiring is connected to the pad semiconductor layer.

20. The method for manufacturing a semiconductor device according to claim 17, 18, or 19, further comprising a step of forming a cap insulating layer on the semiconductor layer, wherein the semiconductor layer and the cap insulating layer are patterned to form the semiconductor layer pattern on which the cap insulating layer is provided.

21. The method for manufacturing a semiconductor device according to any one of claims 17 to 20, wherein the semiconductor layer provided on an under insulating layer is patterned to form the semiconductor layer pattern provided on the under insulating layer.

22. The method for manufacturing a semiconductor device according to any one of claims 17 to 20, further comprising a step of patterning a semiconductor substrate to form the semiconductor layer pattern constituting the semiconductor layer and then providing an isolating insulation layer on the semiconductor substrate, and a step of removing a top surface part of the isolating insulation layer to expose the semiconductor layer pattern so that the semiconductor layer pattern projects upward from the top surface of the remaining isolating insulation film.
